(19) United States
(12) Patent Application Publication
(10) Pub. No.: US 2026/0164929 A1
(43) Pub. Date: Jun. 11, 2026

(54) NANOPARTICLE EMBEDDED FILMS FOR ORGANIC LIGHT EMITTING DEVICES, METHODS OF MAKING, AND METHODS OF USE THEREOF

(71) Applicant: The Regents of the University of Michigan, Ann Arbor, MI (US)

(72) Inventors: Stephen R. Forrest, Ann Arbor, MI (US); Claire Ameson, Ann Arbor, MI (US); Raju Lampande, Ann Arbor, MI (US)

(21) Appl. No.: 19/405,948

(22) Filed: Dec. 2, 2025

Related U.S. Application Data
(60) Provisional application No. 63/730,740, filed on Dec. 11, 2024.

(51) Int. Cl. H10K 50/858; H10K 50/844; H10K 50/854; H10K 102/00

(52) U.S. Cl. CPC H10K 50/858; H10K 50/844; H10K 50/854; H10K 2102/331

(57) ABSTRACT

A film having a first surface, a second surface, a volume between the first surface and the second surface, and one or more nanoparticles, and wherein the volume comprises a polymer.

### CROSS-REFERENCE TO RELATED APPLICATIONS

This application claims priority to U.S. Provisional Application No. 63/730,740 filed on Dec. 11, 2024 incorporated herein by reference in its entirety.

### STATEMENT REGARDING FEDERALLY SPONSORED RESEARCH OR DEVELOPMENT

This invention was made with government support under Grant No. DE-EE0009688 awarded by the U.S. Department of Energy. The government has certain rights in the invention.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety. One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

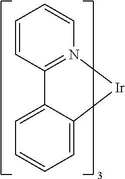

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

In some aspects, the invention relates to a film.

In some embodiments, the film comprises a first surface, a second surface, a volume between the first and second surface, the volume comprising a polymer, and one or more nanoparticles comprising a metal.

In some embodiments, the first surface of the film comprises a micro-scale pattern.

In some embodiments, the micro-scale pattern comprises a microlens array (MLA).

In some embodiments, at least one of the one or more nanoparticles is embedded in the polymer.

In some embodiments, at least one of the one or more nanoparticles is positioned at the second surface.

In some embodiments, at least one of the one or more nanoparticles are embedded in the volume of the film.

In some embodiments, the polymer has an index of refraction larger than 1.5.

In some embodiments, the metal is selected from the group consisting of: Ag, Al, Au, Ir, Pt, Ni, Cu, W, Ta, Fe, Cr, Mg, Ga, Rh, Ti, Ru, Pd, In, Bi, Ca, alloys thereof, mixtures thereof, and stacks thereof.

In some embodiments, the microlens array comprises at least one lens having a diameter of at least 1 μm.

In some embodiments, the microlens array comprises a polygonally close-packed lens arrangement.

In some embodiments, at least one of the one or more nanoparticles has at least one dimension larger than 20 nm.

In some aspects, the invention relates to an OLED stack.

In some embodiments, the OLED stack comprises film comprising a first surface, a second surface, a volume between the first and second surface, the volume comprising a polymer, and one or more nanoparticles comprising a metal.

In some embodiments, the OLED stack comprises a top-emitting OLED stack comprising a bottom layer comprising a substrate and a top layer comprising the film.

In some embodiments, the first surface of the film is positioned at a top of the top layer of the OLED stack.

In some embodiments, the OLED stack comprises a bottom-emitting OLED stack comprising a bottom layer comprising a substrate, and the substrate comprises the film.

In some embodiments, the first surface of the film is positioned at a bottom of the bottom layer of the OLED stack.

In some embodiments, the peak scattering of the one or more nanoparticles of the film is aligned with a wavelength of emission of the OLED stack.

In some aspects, the invention relates to a method of making a film.

In some embodiments, the method comprises the steps of forming a film having a first surface, a second surface, and a volume therebetween, the film comprising a polymer and one or more nanoparticles

In some embodiments, the method further comprises the step of imprinting the first surface of the film to form a pattern.

In some embodiments, the pattern comprises a microlens array (MLA).

In some embodiments, the film is formed against a substrate such that the second surface contacts the substrate.

In some embodiments, the forming step comprises depositing the one or more nanoparticles on a substrate, and depositing a polymer onto the substrate.

In some embodiments, the forming step comprises contacting a solution comprising the polymer and the one or more nanoparticles to the substrate.

In some embodiments, the method further comprises the step of removing the film from a substrate.

In some embodiments, the removal of the film from the substrate comprises chemical lift-off or mechanical peel-off.

In some embodiments, the method further comprises the step of contacting the film to an OLED stack.

In some embodiments, contacting the film to an OLED stack comprises mechanically applying the film to the OLED stack.

In some embodiments, the film is contacted to a first side of the OLED stack such that the second surface of the film contacts the first side of the OLED stack.

In some aspects, the invention relates to a consumer product selected from the group consisting of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a light therapy device, an optical communication device, and a sign.

In some embodiments, the consumer product comprises an OLED stack comprising a film comprising a first surface, a second surface, a volume between the first and second surface, the volume comprising a polymer, and one or more nanoparticles comprising a metal.

In some embodiments, the film is configured to couple polariton modes of the device to air modes at the surface of an electrode of the OLED stack with a 20% to 60% coupling efficiency.

In some aspects, the invention relates to a device.

In some embodiments, the device comprises a substrate, a first electrode, a first organic emissive layer (EML) disposed over the first electrode, the first EML comprising an emissive material, a second electrode disposed over the EML, and a film comprising a first surface, a second surface, a volume between the first and second surface, the volume comprising a polymer, and one or more nanoparticles comprising a metal.

In some embodiments, the first electrode of the device comprises an enhancement layer.

In some embodiments, the second electrode of the device comprises an enhancement layer.

In some embodiments, the device further comprises an enhancement layer disposed over the second electrode.

In some embodiments, the device further comprises an enhancement layer disposed between the first electrode and the second electrode.

In some embodiments, the enhancement layer comprises a plasmonic material exhibiting surface plasmon resonance that non-radiatively couples to the organic emissive material and transfers excited state energy from the organic emissive material to non-radiative mode of surface plasmon polaritons.

In some embodiments, the enhancement layer is provided no more than a threshold distance away from the organic emissive material, wherein the organic emissive material has a total non-radiative decay rate constant and a total radiative decay rate constant due to the presence of the enhancement layer, and the threshold distance is where the total non-radiative decay rate constant is equal to the total radiative decay rate constant.

In some embodiments, the enhancement layer is provided no more than a threshold distance away from the organic emissive material, wherein the organic emissive material has a total non-radiative decay rate constant

$${k}_{non - r ad}^{0} ,$$

a total radiative decay rate constant

$${k}_{ra d}^{0} ,$$

total non-radiative decay rate constant due to the enhancement layer

$${k}_{non - r ad}^{plasmon} ,$$

and a total radiative decay rate constant due to the enhancement layer

$${k}_{r a d}^{p l a s m o n} ;$$

and wherein the threshold distance is a distance at which

$$\frac{{k}_{r a d}^{p l a s m o n}}{{k}_{non - r ad}^{plasmon}} = \frac{{k}_{r ad}^{0}}{{k}_{non - r ad}^{0}} .$$

In some embodiments, the film is positioned on an emission side of the device.

In some embodiments, the film of the device is configured to couple polariton modes of the device to air modes at a surface of the second electrode with a 20% to 60% coupling efficiency. In some embodiments, the film of the device is configured to couple polariton modes of the device to air modes at a surface of the second electrode with a greater than 60% coupling efficiency.

In some embodiments, the peak scattering wavelength of the one or more nanoparticles of the film is aligned with a wavelength of emission of the device.

In some aspects, the invention relates to a consumer product comprising a device having a first electrode, a first organic emissive layer (EML) disposed over the first electrode, the first EML comprising an emissive material, a second electrode disposed over the EML, and a film comprising a first surface, a second surface, a volume between the first and second surface, the volume comprising a polymer, and one or more nanoparticles comprising a metal, wherein the film is disposed over the second electrode.

In some embodiments, the consumer product is selected from the group consisting of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a light therapy device, an optical communication device, and a sign.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 shows an organic light emitting device;

FIG. 2 shows an inverted organic light emitting device that does not have a separate electron transport layer;

FIG. 3 shows an illustration of the fabrication steps for a polymer layer doped with nanoparticles on one surface. The nanoparticle size, shape, distribution, and material can be tuned for a desired emission wavelength;

FIG. 4 shows an illustration of the fabrication steps for a polymer layer doped with nanoparticles throughout. The nanoparticle size, shape, distribution, and material can be tuned for a desired emission wavelength;

FIG. 5A shows an example top emitting device structure;

FIG. 5B shows simulated results of the coupling efficiency to air, waveguide, plasmon and loss modes for a top emitting device of the top emitting device structure shown in FIG. 5A as a function of the electron transporting layer (ETL) thickness with a capping layer of index n=2;

FIG. 5C shows simulated results of the coupling efficiency to air, waveguide, plasmon and loss modes for a top emitting device of the top emitting device structure shown in FIG. 5A as a function of the electron transporting layer (ETL) thickness with a capping layer of index n=1.5;

FIG. 6A shows a schematic of a top-emitting and bottom-emitting device stack;

FIG. 6B shows an exemplary optical microscope image of a microlens array using PixNIL-SFT1;

FIG. 7A shows EQE data for control, MLA, and nanoparticle devices;

FIG. 7B shows JVL data for control, MLA, and nanoparticle devices;

FIG. 8 shows spectra for control, MLA, and nanoparticle devices;

FIG. 9A shows a schematic of an exemplary film;

FIG. 9B shows a schematic of an exemplary film;

FIG. 10A shows a schematic of an exemplary film;

FIG. 10B shows a schematic of an exemplary film;

FIG. 11 shows a schematic of an exemplary method of making a film;

FIG. 12 shows a schematic of an exemplary method of forming a polymer film;

FIG. 13 shows a schematic of an exemplary method of forming a polymer film;

FIG. 14 shows a schematic of a configuration for optical measurements;

FIG. 15 shows a representative scanning electron microscope (SEM) image of 75 nm Ag nanocubes on ALD-grown ZrO₂. Nanocubes were spin coated from a 10 mg/mL suspension in ethanol.

FIG. 16 shows a schematic of modes;

FIG. 17 shows integrated photoluminescence (PL) intensity;

FIG. 18 shows a linecut of integrated PL intensity at k_{⊥}=0;

FIG. 19A shows a graph of PL intensity of a PEP ETL with nanoparticles;

FIG. 19B shows a graph of PL intensity of a SPP ETL with nanoparticles;

FIG. 20 shows a schematic of an exemplary transparent green OLED.

FIG. 21 shows a graph of J-V-L characteristics for control (dots a circles) and NP-enhance devices (dashes and squares);

FIG. 22 shows a schematic of an OLED with a capping layer and a microlens array (MLA);

FIG. 23 shows a graph of normalized intensity against wavelength for a control OLED, an OLED with an MLA, and an OLED with nanoparticles (NPs);

FIG. 24 shows a graph of current density (mA/cm²) and Luminance (cd/m²) against voltage (V) for a control OLED, an OLED with an MLA, and an OLED with nanoparticles (NPs).

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

In some aspects of the present invention, software executing the instructions provided herein may be stored on a non-transitory computer-readable medium, wherein the software performs some or all of the steps of the present invention when executed on a processor.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

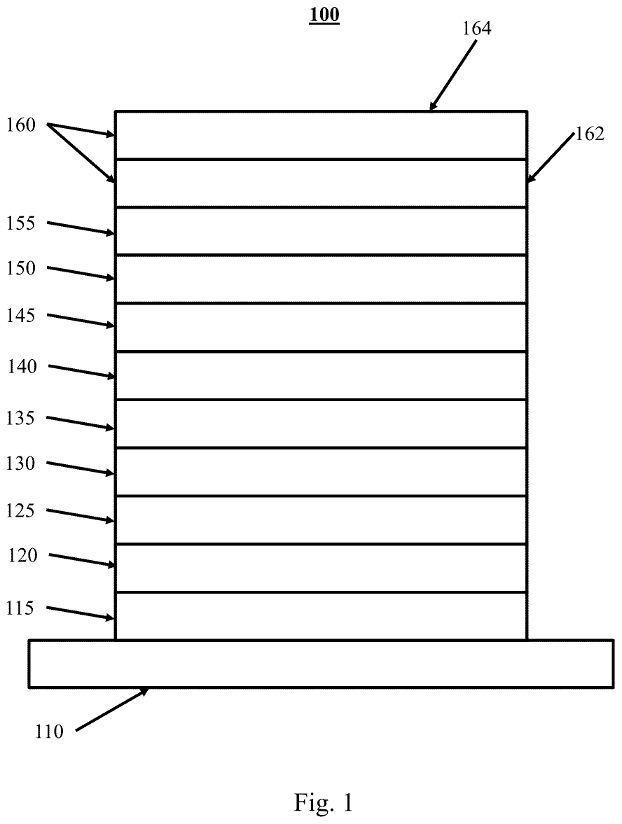

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

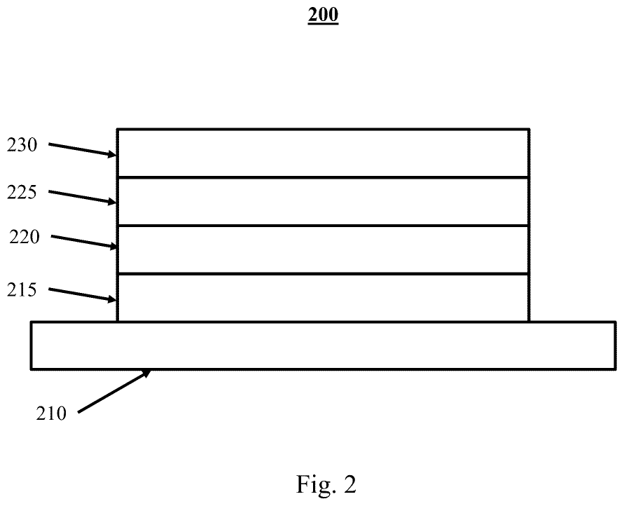

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theaters or stadium screens, light therapy devices, optical communication devices, and signs. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Although exemplary embodiments described herein may be presented as methods for producing particular circuits or devices, for example OLEDs, it is understood that the materials and structures described herein may have applications in devices other than OLEDs. For example, other optoelectronic devices such as organic solar cells and organic photodetectors may employ the materials and structures. More generally, organic devices, such as organic transistors, or other organic electronic circuits or components, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the first emissive material may have a total non-radiative decay rate constant

$${k}_{n o n - r a d}^{0} ,$$

a total radiative decay rate constant

$${k}_{r a d}^{0} ,$$

a total non-radiative decay rate constant due to the enhancement layer

$${k}_{non - r ad}^{plasmon} ,$$

and total radiative decay rate constant due to the enhancement layer

$${k}_{r a d}^{p l a s m o n} ,$$

where the enhancement layer may be disposed not more than the threshold distance from the first emissive material, and where the threshold distance is a distance at which:

$$\frac{{k}_{r a d}^{p l a s m o n}}{{k}_{non - r ad}^{plasmon}} = \frac{{k}_{r ad}^{0}}{{k}_{non - r ad}^{0}}$$

In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

### Film

In some aspects, the invention relates to a film comprising a plurality of nanoparticles. In some embodiments, the film comprises a polymer film embedded with a plurality of nanoparticles. In some embodiments, the film is configured to be applied to a surface of an OLED. For example, the film may be configured to be applied to a light-emitting metal surface of an OLED. In some examples, the film is configured to be applied to the top surface of a top-emitting OLED.

In some examples, the film is configured to be used as a bottom substrate of a bottom-emitting OLED. For example, the film may be configured to such that materials for layers of an OLED stack may be directly deposited onto the film to form the OLED. In some examples, the film is configured to be adhered to an existing bottom substrate of an OLED.

In some examples, the film is configured to be used as a bottom substrate and the top surface of an OLED comprising two transparent electrodes. For example, the film may be configured to be placed adjacent to a top transparent electrode and a bottom transparent electrode of an OLED.

In some embodiments, the film comprises a polymer and a plurality of nanoparticles. In some embodiments, the film is a polymer film embedded with a plurality of nanoparticles.

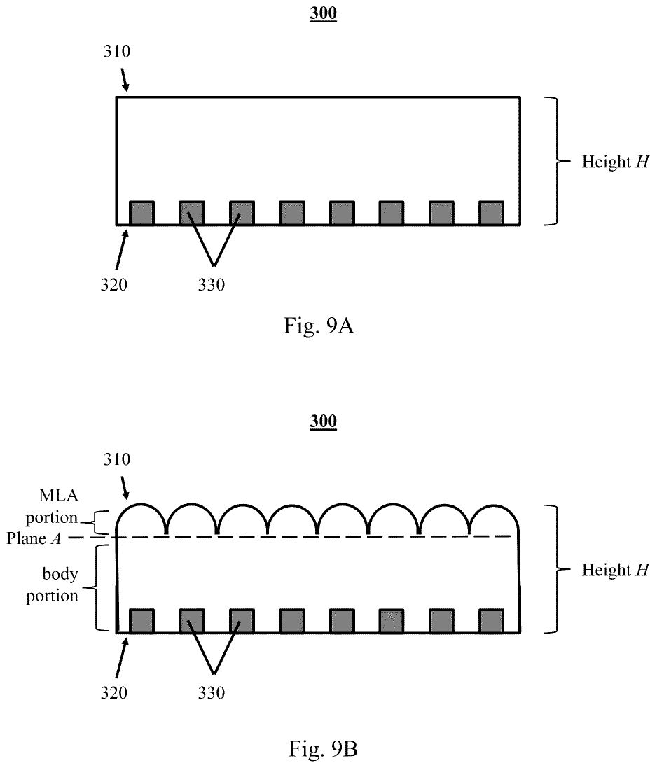

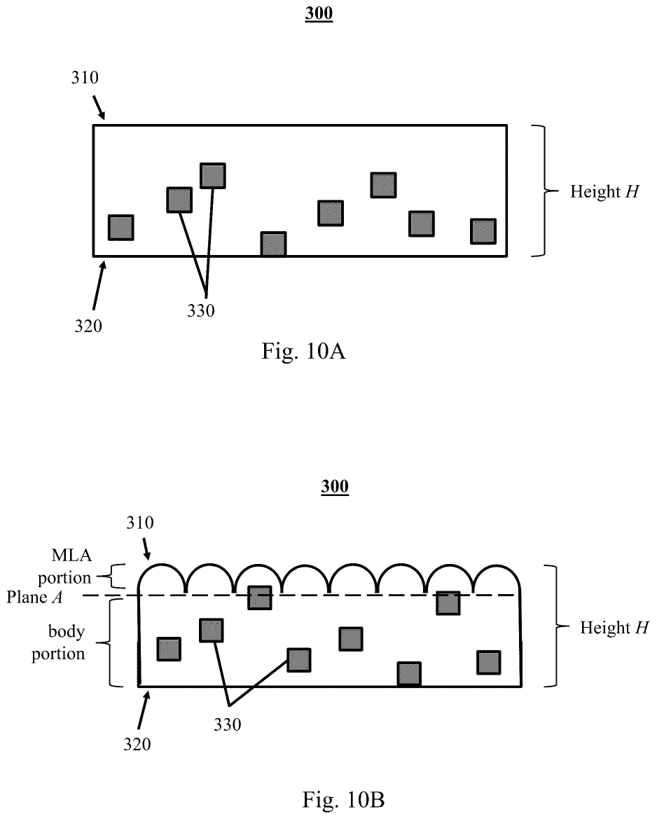

Now referring to FIGS. 9 and 10, in some embodiments film 300 comprises a first surface 310 and a second surface 320 with a height HI therebetween. In some embodiments, film 300 comprises a plurality of nanoparticles 330. In some embodiments, first surface 310 or second surface 320 is textured. For example, first surface 310 or second surface 320 may comprise a micro-scale pattern such as a microlens array (MLA). In some embodiments, neither first surface 310 nor second surface 320 is textured.

As depicted in FIGS. 9 and 10, film 300 may be any height H. The height H may be defined as the length between the peaks of each surface, for example in the case of a textured or microlens array surface. In some embodiments, a thinner film is useful if the polymer of the film has a transparency less than 100% at the emitted wavelengths of interest of an OLED in which the film is configured to be incorporated. In some embodiments, a thicker film is useful for serving as a protection layer and/or encapsulation layer in an OLED.

In some embodiments, the height H of film 300 is or is about 145 nm. In some embodiments the height H of film 300 is in the range of 30 nm to 700 μm, 30 nm to 1 μm, 30 nm to 500 nm, 30 nm to 300 nm, 50 nm to 250 nm, 50 nm to 200 nm, 100 nm to 200 nm, 125 nm to 175 nm, 1 μm to 700 μm, 10 μm to 700 μm, 100 μm to 700 μm, 200 μm to 700 μm, 300 μm to 700 μm, or 100 μm to 500 μm.

First surface 310 and second surface 320 may have any surface area or geometry. In some embodiments, first surface 310 and second surface 320 are any curvilinear surface. In some embodiments, first surface 310 and second surface 320 are flat surfaces. In some embodiments, first surface 310 and second surface 320 are opposite each other. In some embodiments, first surface 310 and second surface 320 are parallel, substantially parallel, or about parallel to each other. In some embodiments, first surface 310 and second surface 320 deviate from parallel relative to each other by any angle. For example, first surface 310 and second surface 320 may deviate from parallel relative to each other by or by about 1°, 2°, 3°, 4°, 5°, 10°, 15°, 20°, 25°, or 30°. For example, first surface 310 and second surface 320 may deviate from parallel relative to each other by in the range of 0° to 30°. For example, first surface 310 and second surface 320 may deviate from parallel relative to each other by less than 1°, 2°, 3°, 4°, 5°, 10°, 15°, 20°, 25°, or 30°. In some embodiments, first surface 310 and second surface 320 are parallel to each other and have the same surface area and geometry. In some embodiments, the surface area and geometry of first surface 310 and second surface 320 are configured to match the surface area and geometry of one or more layers of an OLED stack.

In some embodiments, as in FIG. 9A and FIG. 9B, the plurality of nanoparticles 330 are embedded such that each nanoparticle 330 is positioned at the same height or about the same height in film 300. For example, each nanoparticle 330 may be positioned substantially in a plane parallel to first surface 310 and/or second surface 330. Each nanoparticle 330 in a plane may be positioned at any defined spatial pattern for example nanoparticles 330 may be positioned with regular spacings between each nanoparticle 330 within the plane. For example, nanoparticles 330 may be positioned in a grid. In some embodiments, each nanoparticle 330 in a plane is positioned randomly. In some embodiments, the plurality of nanoparticles 330 may be positioned such that each nanoparticle 330, or any number of nanoparticles 330, is or is about 200 nm or 100 nm from the nearest neighboring nanoparticle 330. In some embodiments, the plurality of nanoparticles 330 may be positioned such that each nanoparticle 330, or any number of nanoparticles 330, is at least 200 nm or at least 100 nm from the nearest neighboring nanoparticle 330. In some embodiments, the plurality of nanoparticles 330 may be positioned such that each nanoparticle 330, or any number of nanoparticles 330, is at least about 200 nm or at least about 100 nm from the nearest neighboring nanoparticle 330. In some embodiments, the plurality of nanoparticles 330 may be positioned such that each nanoparticle 330, or any number of nanoparticles 330, is less than or less than about an OLED emission wavelength from the nearest neighboring nanoparticle 330. In some embodiments, the plurality of nanoparticles 330 may be positioned such that each nanoparticle 330, or any number of nanoparticles 330, is at least 100 nm from the nearest nanoparticle 330 and less than an OLED emission wavelength from the nearest nanoparticle 330. In some embodiments, the plurality of nanoparticles 330 are positioned randomly such that the average distance between each nanoparticle 330 is in the range of 100 nm to 200 nm. In some embodiments, the plurality of nanoparticles 330 are positioned randomly such that the average distance between each nanoparticle 330 is at least 100 nm or at least 200 nm. In some embodiments, the plurality of nanoparticles 330 are positioned randomly such that the average distance between each nanoparticle 330 is at least about 100 nm or at least about 200 nm. In some embodiments, the plurality of nanoparticles 330 are positioned randomly such that the average distance between each nanoparticle 330 is less than or less than about an OLED emission wavelength. The OLED emission wavelength may be any wavelength an OLED is configured to emit.

In some examples, the spacing between nanoparticles 330 may be defined as the center to center distance between nanoparticles 330. In some examples, the spacing between nanoparticles 330 may be defined as the distance from the edge of a first nanoparticle 330 to the edge of a second nanoparticle 330. In this example, the spacing may be dependent on nanoparticle 330 dimensions.

There may be any density of nanoparticles 330 in a plane. The density may be defined as number of nanoparticles per surface area of the plane. In some embodiments, the density of nanoparticles in a plane is in the range of 10 to 30, 10 to 20, 20 to 30, or 15 to 25 nanoparticles per μm². In some embodiments, the density of nanoparticles in a plane is or is about 10, 15, 20, 25, or 30 nanoparticles per μm².

In some embodiments, one of first surface 310 and second surface 320 is textured. For example, as depicted in FIG. 9B, first surface 310 may be textured. In some embodiments, the plurality of nanoparticles 330 are embedded at or near second surface 320. In some embodiments, the plurality of nanoparticles 330 are positioned on top of second surface 320. In this embodiment, first surface 310 may be textured. In some examples, the plurality of nanoparticles 330 are embedded in the film such that a portion of a surface of each nanoparticle 330 forms a portion of second surface 320. In some examples, the plurality of nanoparticles 330 are embedded in the film such that each nanoparticle is just under second surface 320. For example, a nanoparticle 330 may be positioned in the film at a distance in the range of 0 nm to 30 nm from second surface 320. For example, a nanoparticle 330 may be positioned in the film at a distance of or of about 0 nm, 1 nm, 2 nm, 3 nm, 4 nm, 5 nm, 10 nm, 15 nm, 20 nm, 25 nm, or 30 nm from second surface 320. The distance may be measured from the center of nanoparticle 330 or edge of nanoparticle 330 nearest to second surface 320. For example, film 300 may be formed by first patterning a plurality of nanoparticles 330 onto a substrate surface in any desired 2D pattern or a random pattern, then a polymer may be positioned onto the substrate surface and cured forming an embodiment of film 300 in which the plurality of nanoparticles 330 are embedded in film 300 in a plane at or near the film 300 surface that is against the substrate surface.

In some embodiments, the plurality of nanoparticles 330 are embedded at or near second surface 320 and at or near first surface 310. In some embodiments, the plurality of nanoparticles 330 are positioned on top of second surface 320 and on top of first surface 310. In some examples, the plurality of nanoparticles 330 are embedded in the film such that a portion of a surface of each nanoparticle 330 forms a portion of second surface 320 or a portion. In some examples, the plurality of nanoparticles 330 are embedded in the film such that each nanoparticle is either just under second surface 320 or just under first surface 310.

In some embodiments, the plurality of nanoparticles 330 are embedded such that each nanoparticle 330 is positioned at a plane parallel to first surface 310 and/or second surface 320. The plane may be any distance from first surface 310 and second surface 320. In some embodiments, the plurality of nanoparticles 330 are embedded such that each nanoparticle 330 is positioned at a height that is the midpoint or about the midpoint between first surface 310 and second surface 320. For example, a first portion of film 300 may be formed such that the plurality of nanoparticles 330 are embedded in the first portion of film 300 in a plane at or near a surface of the first portion of film 300. Subsequently, a second portion of film 300 may be formed by positioning a polymer against the surface of the first portion of film 300 at which the plurality of nanoparticles are embedded. The positioned polymer may then be cured thereby adhering the polymer to the first portion of film 300 thereby forming film 300. In this embodiment, the plurality of nanoparticles 330 may be positioned at any height of the film depending on the heights chosen for the first and second portions of film 300. This process may be performed sequentially to form film 300 with any number of planes having a plurality of nanoparticles 330 with each plane being at any height of film 300. For example, the positions of the planes having a plurality of nanoparticles 330 may be at any height of the film such that the plurality of nanoparticles 330 are positioned in a textured surface such as a microlens array only, positioned in the portion of the film 300 that does not make up a textured surface only, or positioned such that the plurality of nanoparticles 330 are positioned in a textured surface of film 300 and in a portion of film 300 that does not make up a textured surface. In embodiments in which the plurality of nanoparticles 330 are positioned in a textured surface only, the portion of the film that does not make up the textured surface may have a height of less than or less than about 30 nm. In embodiments in which the plurality of nanoparticles 330 are positioned in a textured surface only, the portion of the film that does not make up the textured surface may have a height of or of about 5 nm, 10 nm, 15 nm, 20 nm, 25 nm, or 30 nm. In some embodiments, the plurality of nanoparticles 330 are positioned at a height such that they are just underneath an MLA of a surface. For example, the plurality of nanoparticles 330 may be in a plane that is at or near the shortest point of an MLA. The plane at the shortest point of the MLA is denoted as Plane A in FIGS. 9B and 10B.

In some embodiments, as in FIGS. 10A and 10B, the plurality of nanoparticles 330 are embedded throughout film 300. In some embodiments, the plurality of nanoparticles 330 are embedded randomly throughout film 300. The plurality of nanoparticles 330 may be embedded throughout the film at any density. The plurality of nanoparticles 330 may be embedded throughout the film at a density such that the spacing between nanoparticles 330 is less than or equal to the emission wavelength of an OLED into which the film is desired to be incorporated. The spacing may be defined as the distance between the nearest edge of two nanoparticles 330, and therefore the density that relates to a desired spacing may depend on the dimensions of nanoparticles 330. The plurality of nanoparticles may be embedded throughout the film at a density in the range of 50 to 100 nanoparticles per μm³, about 50 to 100 nanoparticles per μm³, or about 50 to about 100 nanoparticles per μm³. The plurality of nanoparticles 330 may be embedded throughout the film at a density of or of about 50, 55, 60, 65, 70, 75, 80, 85, 90, 95, or 100 nanoparticles per μm³.

In some embodiments, one of first surface 310 and second surface 320 is textured. For example, as depicted in FIG. 10B, first surface 310 may be textured. In some embodiments, one of first surface 310 and second surface 320 comprises an MLA. In some embodiments, the density of nanoparticles in any lens of an MLA is such that the spacing between nanoparticles 330 is less than or equal to the emission wavelength of an OLED into which the film is desired to be incorporated. The spacing may be defined as the distance between the nearest edge of two nanoparticles 330, and therefore the density that relates to a desired spacing may depend on the dimensions of nanoparticles 330. The density of nanoparticles 330 in a lens of an MLA may be in the range of 50 to 100 nanoparticles per μm³, about 50 to 100 nanoparticles per μm³, or about 50 to about 100 nanoparticles per μm³. The density of nanoparticles 330 in a lens of an MLA may be or may be about 50, 55, 60, 65, 70, 75, 80, 85, 90, 95, or 100 nanoparticles per μm³.

In some embodiments, the plurality of nanoparticles are embedded throughout a portion of film 300. For example, a first portion of film 300 may be formed with embedded nanoparticles throughout the first portion of film 300. Subsequently, any polymer layers may be added to either side of the first portion of film 300 such that a top portion, bottom portion, middle portion, and/or any number of middle layers of film 300 comprises any density of embedded nanoparticles 330. The top portion, bottom portion, middle portion, or and/or the any number of middle layers of film 300 may be any height. In some embodiments, only a portion of film 300 that comprises a textured surface comprises embedded nanoparticles. In some embodiments, only a portion of film 300 that does not comprise a textured surface comprises embedded nanoparticles. For example, as depicted in FIGS. 9B and 10B, film 300 may comprise a body portion and an MLA portion. In some embodiments, only the body portion comprises embedded nanoparticles. In some embodiments, only the MLA portion comprises embedded nanoparticles. In embodiments in which only the MLA portion comprises embedded nanoparticles, the body portion may be less than or less than about 30 nm. In embodiments in which only the MLA portion comprises embedded nanoparticles, the body portion may be or may be about 30 nm, 25 nm, 20 nm, 15 nm, 10 nm, or 5 nm. In some embodiments, the volume of the portion of the film in which nanoparticles 330 are embedded is chosen to increase scattering and minimize absorption. Increased scattering may lead to outcoupling into air modes when the film is incorporated into an OLED. For example, in cases in which the volume of the portion of the film in which nanoparticles 330 are embedded is high, there may be greater luminance loss of an OLED stack due to absorption.

It should be appreciated that any combination of positions of plurality of nanoparticles 330 described herein may be incorporated in a single embodiment of film 300. For example, film 300 may comprise a plurality of nanoparticles 330 embedded in any plane including any surface of film 300 while further comprising a plurality of nanoparticles 330 embedded in any portion of volume of film 300. For example, film 300 may comprise nanoparticles 330 embedded at or near first surface 310, on top of first surface 310, at or near second surface 320, on top of second surface 320, embedded in any number of planes at any heights of film 300, embedded throughout film 300, embedded in any portions of film 300 spanning any film 300 heights, or any combinations thereof. It should also be appreciated that any surface of film 300 may be textured. For example, a film surface having one or more nanoparticles at or near the film surface may be textured.

The density of nanoparticles in one or more planes of film 300 or the density of nanoparticles 330 throughout the volume of film 300 or any portion of the volume of film 300 may relate to the amount of scattering into visible air modes and/or absorption in the nanoparticles when film 300 is incorporated in an OLED. Similarly, the fraction of the volume of a film having embedded nanoparticles 330 may relate to the amount of scattering into visible air modes and/or absorption in the nanoparticles when film 300 is incorporated in an OLED. For example, the density of nanoparticles 330 in film 300 may be chosen such that there is high scattering into visible air modes and low absorption in the nanoparticles 330. The probability of photons scattering off of nanoparticles may be determined by the density of nanoparticles across the emission surface of an OLED. The density of nanoparticles 330 may be chosen to balance enhancement and absorption of light that enters film 300 optionally from an OLED. For example, a lower density of nanoparticles 330 may relate to decreased enhancement and/or absorption. For example, a higher density of nanoparticles 330 may relate to increased enhancement and/or absorption. For example, the density of nanoparticles 330 may be chosen such that light entering film 300 encounters at least some nanoparticles 330 while also allowing a substantial portion of light to pass through film 300. Embodiments of film 300 having a high density of nanoparticles 330 may primarily absorb light.

Nanoparticle 330 may be any nanoparticle. In some embodiments, nanoparticle 330 comprises a metal such as Ag, Al, Au, Ir, Pt, Ni, Cu, W, Ta, Fe, Cr, Mg, Ga, Rh, Ti, Ru, Pd, In, Bi, or Ca. In some embodiments, nanoparticle 330 comprises Ag, Al, Au, Ir, Pt, Ni, Cu, W, Ta, Fe, Cr, Mg, Ga, Rh, Ti, Ru, Pd, In, Bi, or Ca. In some embodiments, nanoparticle 330 comprises a metal oxide. In some embodiments, nanoparticle 330 comprises an oxide of Ag, Al, Au, Ir, Pt, Ni, Cu, W, Ta, Fe, Cr, Mg, Ga, Rh, Ti, Ru, Pd, In, Bi, or Ca. In some embodiments, nanoparticle 330 comprises TiO₂ or Ag. In some embodiments, nanoparticle 330 comprises any alloy, mixture, or stack having one or more of the following elements: Ag, Al, Au, Ir, Pt, Ni, Cu, W, Ta, Fe, Cr, Mg, Ga, Rh, Ti, Ru, Pd, In, Bi, and Ca. In some embodiments, nanoparticle 330 comprises a metal sphere having a coating. In some embodiments, the coating forms a shell around the metal sphere. The shell formed around the metal sphere may be any thickness. In some examples, the shell formed around the metal sphere is less than 10 nm, less than about 10 nm, less than 5 nm, or less than about 5 nm thick. In some example, the shell formed around the metal sphere is in the range of 1 to 10 nm thick. In some example, the shell formed around the metal sphere is or is about 10 nm, 9 nm, 8 nm, 7 nm, 6 nm, 5 nm, 4 nm, 3 nm, 2 nm, or 1 nm. In some embodiments, the coating comprises any shell material such silica or a metal oxide. A coating forming a shell may aid in preventing aggregation of nanoparticles 330 while preserving the plasmonic effect. In some embodiments, nanoparticle 330 comprises a nanosphere.

Nanoparticle 330 may be any dimensions or geometry. In some embodiments, nanoparticle 330 comprises a sphere, a cube, a rectangular prism, a rod. In some embodiments, nanoparticle 330 is a sphere or cube having a diameter or length of or of about 20 nm or 75 nm. In some embodiments, nanoparticle 330 is a sphere or cube having a diameter or length in the range of 20 nm to 75 nm. In some embodiments, the diameter or length of the plurality of nanoparticles 330 relates to the performance of film 300 when film 300 is incorporated in an OLED stack. For example, larger diameter or larger length nanoparticles 330 may result in enhanced performance of film 300. In some embodiments, each nanoparticle 330 of film 300 is an identical nanoparticle. In some embodiments, the plurality of nanoparticles 330 comprises a mixture of nanoparticles.

In some embodiments, first surface 310 and/or second surface 320 is a textured surface such as a microscale-patterned surface. In some embodiments, the microscale-pattern comprises any microlens array (MLA) pattern known in the art. In some embodiments, the MLA pattern comprises any close-packed structure such as randomly close-packed lenses. The bottom surface of the MLA may be any polygon such as a regular polygon or an irregular polygon. In some embodiments, the MLA pattern is a hexagonally close-packed arrangement. In some embodiments, the MLA pattern is a polygonally close-packed arrangement. In some embodiments, there is no planar space or minimal planar space between lenses of the MLA pattern. For example, the MLA pattern may have close-packed features such that there are no or minimal planar regions between features. Exemplary feature shapes include hemispheres, cones, and pyramids. The lens diameter of each lens of the MLA pattern may be any length. In some embodiments, each lens of the MLA pattern has the same diameter. In some embodiments, the lens diameter length is configured to reach a desired or maximal outcoupling efficiency when incorporating film 300 in a device. In some embodiments, the lens diameter is or is at least 1 μm. In some embodiments, the lens diameter is smaller than an OLED emission area onto which film 300 is configured to be incorporated. In some embodiments, first surface 310 or second surface 320 is textured by imprinting a micro-scale pattern onto the surface.

In some embodiments, film 300 comprises a polymer. In some embodiments, film 300 comprises a polymer film embedded with a plurality of nanoparticles 330. In some embodiments, the polymer of film 300 comprises a single polymer species or a mixture of polymer species. In some embodiment, the polymer of film 300 comprises poly(methylmethacrylate) (PMMA) and/or polydimethylsiloxane (PDMS). In some embodiments, the polymer of film 300 comprises a polymer blend such as Norland products high-index epoxy NOA170 and/or Pixelligent materials. In some embodiments, the polymer has an index of refraction of or about 2.0, 1.85, 1.7, or 1.5. In some embodiments, the polymer has an index of refraction in the range of 1.5 to 2.0, 1.85 to 2.0, 1.6 to 1.9, 1.8 to 1.9, 1.8 to 2.0, or 1.9 to 2.0. In some embodiments, the polymer has an index of refraction of greater than 1.5, greater than about 1.5, greater than 1.7, or greater than about 1.7. In some embodiments, the index of refraction of the polymer is chosen such that a desired or maximal fraction of light is coupled to plasmon modes when film 300 is incorporated in an OLED stack. In some embodiments, the index of refraction of the polymer is chosen to be greater than or equal to the index of refraction of an emissive layer of an OLED stack in which film 300 is desired to be incorporated. In some embodiments, the index of refraction of the polymer is chosen to be about equal to the index of refraction of an emissive layer of an OLED stack in which film 300 is desired to be incorporated. The polymer may be any density.

In some embodiments, the geometry of film 300, nanoparticle 330 positioning and density in film 300, and/or textured surface pattern of film 300 are chosen for a desired plasmon outcoupling efficiency when film 300 is incorporated in an OLED. The outcoupling efficiency may depend on the amount of light coupled to waveguide and plasmonic modes. For example, an embodiment of film 300 that comprises a plane having a plurality of nanoparticles 330 as in FIG. 9 may outcouple about 20% of plasmonic modes. For example, an embodiment of film 300 that comprises nanoparticles 330 embedded throughout film 300 may couple greater than 20% of plasmonic modes and/or may outcouple in the range of 40% to 60% of waveguide modes.

### Method of Making a Film

In some aspects, the invention relates to a method of making a film. The film may be an embodiment of film 300.

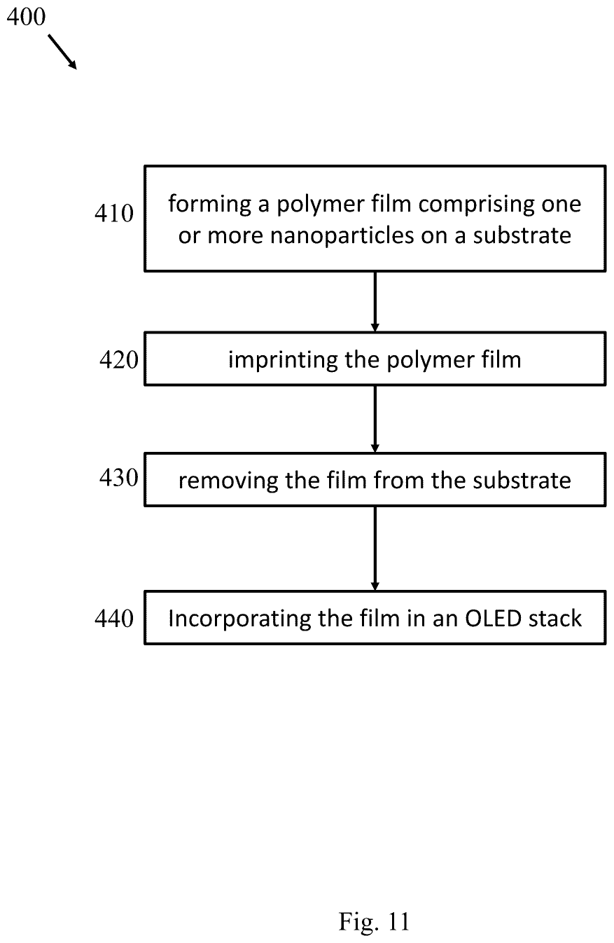

Now referring to FIG. 11, in some embodiments the method of making the film comprises method of making a film 400. In some embodiments method 400 comprises the step of 410 forming a polymer film comprising one or more nanoparticles on a substrate. In some embodiments, the method further comprises the step of 420 imprinting the polymer film. In some embodiments, method 400 further comprises the step of 430 removing the film from the substrate. In some embodiments, method 400 further comprises the step of 440 applying the film to an OLED stack. In some embodiments, the resulting film derived by method 400 comprises a polymer film having embedded nanoparticles at or near a surface of the film. For example, the embedded nanoparticles may each be at the same surface of the film or the same plane near the surface of the film. In some embodiments, the resulting film derived by method 400 comprises a polymer film having embedded nanoparticles throughout the volume of the film.

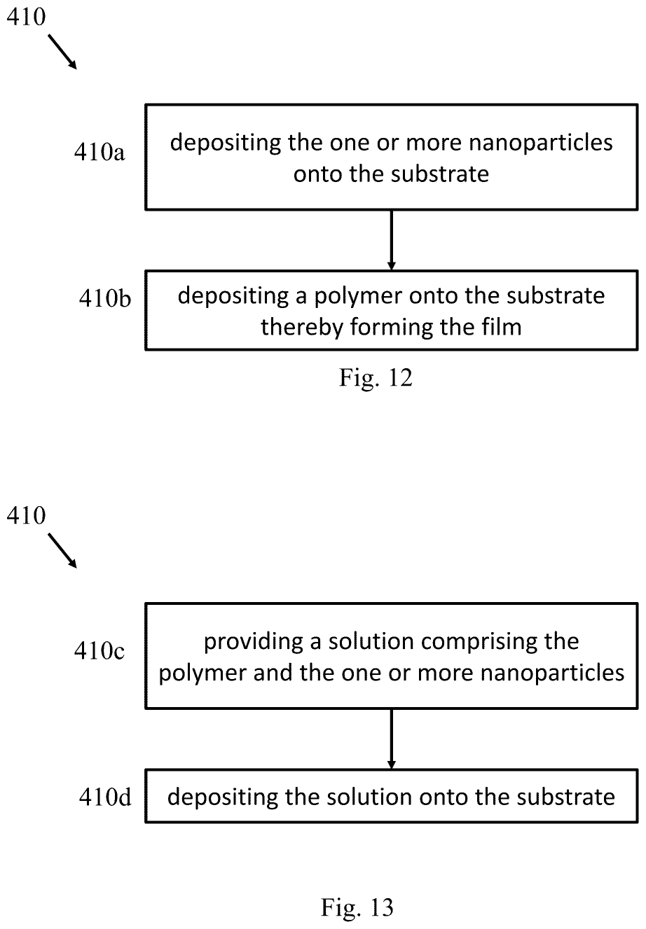

Now referring to FIG. 12, in some embodiments, the step of 410 forming the polymer film comprising one or more nanoparticles on a substrate comprises the steps of 410a depositing the one or more nanoparticles onto the substrate and 410b depositing a polymer onto the substrate thereby forming a film. In using this embodiment of step 410 the resulting film derived by method 400 may comprise a polymer film having embedded nanoparticles at or near a surface of the film. For example, the embedded nanoparticles may each be at the same surface of the film or at a plane of the same height near a surface of the film.

In some embodiments, step 410 comprises the step of 410a depositing one or more nanoparticles onto a substrate. The nanoparticles may be deposited onto the substrate using any method known in the art for positioning nanoparticles onto a substrate. In some embodiments, the nanoparticles are deposited onto the substrate via solution. In this embodiment, the substrate may comprise a holder substrate. In some embodiments, the nanoparticles are deposited onto the substrate by a lithography method. For example, the substrate may comprise a metal film and nanoparticles may be patterned onto the substrate using a lithography method. In some embodiments, the nanoparticles are nano-scale patterned onto the substrate.

The nanoparticles may be deposited onto the substrate to result in any density and/or pattern of nanoparticles on the substrate. The deposited pattern and density of nanoparticles on the substrate may be the resulting pattern and density of nanoparticles in a plane of a film forms by the method. The pattern and density of deposited nanoparticles on the substrate may be any pattern and density described herein for the pattern and density of nanoparticles 330 in a plane of film 300.

The nanoparticles may be deposited onto the substrate resulting in any density of nanoparticles on the surface of the substrate. The density may be measured in terms of number of nanoparticles per substrate surface area. In some embodiments, the density of nanoparticles on the substrate is chosen such that there is high scattering into visible air modes and low absorption in the nanoparticles in the resulting film formed by the method.

In some embodiments, nanoparticles are deposited in a defined spatial pattern for example nanoparticles may be deposited on the substrate with regular spacings between each nanoparticle. For example, nanoparticles may be deposited in a grid pattern. In some embodiments, nanoparticles are deposited in random positions on the substrate. In some embodiments, each deposited nanoparticle, or any number of deposited nanoparticles, is or is about 200 nm or 100 nm from the nearest neighboring nanoparticle. In some embodiments, each deposited nanoparticle, or any number of deposited nanoparticles, is at least 200 nm or at least 100 nm from the nearest neighboring nanoparticle. In some embodiments, each deposited nanoparticle, or any number of deposited nanoparticles, is at least about 200 nm or at least about 100 nm from the nearest neighboring nanoparticle. In some embodiments, each deposited nanoparticle, or any number of deposited nanoparticles, is less than or less than about an OLED emission wavelength from the nearest neighboring nanoparticle. In some embodiments, each deposited nanoparticle, or any number of deposited nanoparticles, is at least 100 nm from the nearest nanoparticle 330 and less than an OLED emission wavelength from the nearest nanoparticle 330. In some embodiments, nanoparticles are deposited randomly such that the average distance between each nanoparticle is in the range of 100 nm to 200 nm. In some embodiments, nanoparticles are deposited randomly such that the average distance between each nanoparticle is at least 100 nm or at least 200 nm. In some embodiments, nanoparticles are deposited randomly such that the average distance between each nanoparticle is at least about 100 nm or at least about 200 nm. In some embodiments, nanoparticles are deposited randomly such that the average distance between each nanoparticle is less than or less than about an OLED emission wavelength. The OLED emission wavelength may be any wavelength an OLED is configured to emit. The OLED emission wavelength may be any wavelength an OLED in which the resulting film of the method is desired to be incorporated is configured to emit.

The nanoparticles may be any nanoparticle. The nanoparticles may be any plurality of nanoparticles described herein for use in film 300.

In some embodiments, step 410 comprises the step of 410b depositing a polymer onto the substrate. In some embodiments, the polymer is deposited onto the substrate subsequent to the step of depositing nanoparticles onto the substrate. In other words, the polymer may be deposited onto a substrate having one or more nanoparticles. Any method known in the art for positioning a polymer onto a substrate may be used. The polymer may be deposited by any solution or gel-processing technique such as spin coating, slot die coating, doctor blade, or drop casting. The polymer may be uncured or only partially cured. The polymer may remain uncured or only partially cured until after step 420 imprinting the polymer film. In some embodiments, the polymer is cured prior to step 420 imprinting the polymer film. The polymer may be deposited onto the substrate such that the polymer forms a film of any desired height. The desired height may be any height. The desired height may be any height described herein for film 300.

The polymer may comprise any polymer. The polymer may comprise any polymer described herein for use in film 300.

Now referring to FIG. 13, in some embodiments, the step of 410 forming the polymer film comprising one or more nanoparticles on a substrate comprises the steps of 410c providing a solution comprising the polymer and the one or more nanoparticles and 410d depositing the solution onto the substrate.

The solution comprising a polymer and one or more nanoparticles may comprise any concentration of nanoparticles, any concentration of polymer, and/or any solvent. The concentration of nanoparticles in the solution may relate to the density of embedded nanoparticles in a film formed by the method. The density of embedded nanoparticles in the resulting film may be any density of nanoparticles. The density of embedded nanoparticles in the resulting film may be any density of nanoparticles described herein for film 300 or portion thereof. In some embodiments, the concentration of nanoparticles in the solution is chosen such that there is high scattering into visible air modes and low absorption in the nanoparticles of a film formed by the method 400. In some embodiments, the solvent of the solution is chosen such that the nanoparticles do not aggregate or are unlikely to aggregate in solution. The solvent may be chosen based on the composition of the nanoparticles. In some embodiments, the solvent comprises anisole and/or ethanol.

In some embodiments, the step of 410c providing a solution comprising the polymer and the one or more nanoparticles comprises combining a first solution comprising the one or more nanoparticles and a second solution comprising one or more polymer molecules. The nanoparticles may be any nanoparticles. The nanoparticles may be any plurality of nanoparticles described herein for use in film 300. In some embodiments, forming the first solution comprising one or more nanoparticles comprises dispersing or dissolving one or more nanoparticles in solution. The one or more nanoparticles may be dissolved in any solvent. In some embodiments, the solvent is chosen such that the nanoparticles do not aggregate in solution or are unlikely to aggregate in solution. In some embodiments, the solvent comprises ethanol. The first solution may comprise any concentration of nanoparticles.

The one or more polymer molecules of the second solution may comprise any polymer species. In some embodiments, the one or more polymer molecules of the second solution may comprise any polymer species described herein for use in film 300. The second solution comprising one or more polymer molecules may be a miscible solution. The one or more polymer molecules may be dissolved in any solvent. In some embodiments, the solvent comprises anisole. The second solution may comprise any concentration of polymer molecules.

In some embodiments, combining the first solution and second solution comprises mixing the solutions. In some embodiments, combining the first solution comprises adding the first solution to the second solution or adding the second solution to the first solution.

In some embodiments, the step of 410 forming the polymer film comprising one or more nanoparticles on a substrate comprises the step of 410d depositing the solution comprising a polymer and one or more nanoparticles onto the substrate. Any method known in the art for positioning a polymer solution onto a substrate may be used. The solution comprising a polymer and one or more nanoparticles may be deposited by any solution or gel-processing technique such as spin coating, slot die coating, doctor blade, or drop casting. The polymer of the solution may be uncured or only partially cured. The polymer may remain uncured or only partially cured until after step 420 imprinting the polymer film. In some embodiments, the polymer is cured prior to step 420 imprinting the polymer film. In some embodiments, depositing the solution comprising a polymer and one or more nanoparticles onto the substrate is performed such that the solution forms a film of any desired height on the substrate.

In some embodiments, polymer layers of any height, optionally comprising a plurality of nanoparticles, may be added to any surface of the polymer film prior to step 420 imprinting the polymer film. For example, adding layers may allow for the plurality of nanoparticles of the film to be positioned at a height of any plane or embedded throughout any portion of the film. For example, adding a layer that is or is about the same height as the polymer film to the surface of the polymer film comprising nanoparticles may result in a film having a plurality of nanoparticles positioned at a plane at the midpoint of the film. In some embodiments, step 410 may be repeated any number of times adding sequential polymer portions, optionally comprising nanoparticles 330, to the film prior to step 420 imprinting the polymer film. In this embodiment, any number of nanoparticle embedded planes or portions may be formed in the polymer film. In some embodiments, the polymer film is cured prior to the addition of any polymer layers to the film. For example, a polymer solution optionally further comprising nanoparticles may be deposited onto the cured polymer film. The polymer solution may then be cured such that a polymer layer is formed on the film surface.

In some embodiments, the initial polymer film does not comprise nanoparticles, but rather one or more additional polymer layers comprises nanoparticles. For example, the first polymer film may be formed by depositing a polymer solution onto a substrate and subsequently curing the polymer solution to form the polymer film. In this embodiment, a polymer solution comprising one or more nanoparticles may be deposited onto the polymer film forming a film having a portion comprising one or more nanoparticles embedded throughout the portion.

Now referring back to FIG. 11, in some embodiments, method 400 comprises the step of 420 imprinting the polymer film. In some embodiments, the polymer film is outgassed and/or desiccated prior to imprinting. In some embodiments, the polymer film is outgassed and/or desiccated via a vacuum chamber. In some embodiments, the polymer film is uncured during imprinting. In some embodiments, the polymer film is partially cured prior to imprinting. Partially curing the polymer film may be beneficial in cases in which it is difficult to cure the polymer film once the imprinting mold is positioned against the film. In some embodiments, the polymer film is cured during imprinting and/or subsequent to imprinting. In some embodiments, the polymer film is imprinted prior to removing the polymer film from the substrate. In some embodiments, the polymer film is imprinted on the surface of the polymer film that is opposite the substrate. In some embodiments, the polymer film is imprinted by the use of a mold. For example, a surface of the polymer film may be imprinted by contacting a mold against the surface. The mold may be any mold. In some embodiments, the mold comprises glass, polydimethylsiloxane, and/or any other material known in the art for molds configured to imprint a polymer film. In some embodiments, the mold is coated with a release layer prior to imprinting the film. The release layer may be less than 5 nm, 4 nm, 3 nm, 2 nm, or 1 nm thick. The release layer may be in the range of 1 nm to 5 nm thick. The release layer may be or may be about 1 nm, 2 nm, 3 nm, 4 nm, or 5 nm thick. The composition and thickness of the release layer may be chosen to prevent bonding between the mold and the polymer film.

In some embodiments, a surface of the polymer film is imprinted such that the imprinted surface comprises a micro-scale pattern such as an MLA. The MLA may be any MLA described herein for embodiments of film 300. In some embodiments, the polymer film comprises an additional polymer layer and step 420 comprises imprinting the surface of the additional polymer layer. In some embodiments, the film comprises a first portion having one or more embedded nanoparticles and a second portion that does not have nanoparticles. In this embodiment, step 420 may comprise imprinting the first portion or the second portion. In some examples, step 420 comprises imprinting the first portion forming a film in which only the MLA comprises nanoparticles. In some examples, step 420 comprises imprinting the second portion forming film in which only the body portion of the film comprises nanoparticles.

In some embodiments, step 420 may not be performed. In this embodiment, first and second surfaces of a resulting film of method 400 may not be textured.

In some embodiments, method 400 further comprises the step of 430 removing the film from the substrate. Any method known in the art for removing a polymer from a substrate may be used. In some embodiments, the film is removed from the substrate subsequent to curing the polymer of the film. In some embodiments, the film is removed chemically or mechanically. For example, the film may be removed via nay methods known in the art for chemical lift-off or mechanical peel-off of a polymer from a substrate.

In some embodiments, polymer layers of any height, optionally comprising a plurality of nanoparticles, may be added to the non-imprinted surface of the polymer film after step 430 removing the film from the substrate. For example, polymer layers may be added subsequent to imprinting the polymer film similarly to methods described herein for adding polymer layers prior to imprinting. For example, adding layers may allow for the plurality of nanoparticles of the film to be positioned at a height of any plane or embedded throughout any portion of the film. For example, adding a layer that is or is about the same height as the polymer film to the surface of the polymer film comprising nanoparticles may result in a film having a plurality of nanoparticles positioned at a plane at the midpoint of the film. In some embodiments, step 410 may be repeated any number of times after step 430 removing the film from the substrate adding sequential polymer portions, optionally comprising nanoparticles 330, to the non-imprinted surface of the film. In this embodiment, any number of nanoparticle embedded planes or portions may be formed in the polymer film.

In some embodiments, step 430 is performed prior to step 420 imprinting the polymer film. In this embodiment, the method may allow for imprinting either surface of film 300. For example, imprinting the polymer film after removal may allow for imprinting a surface of the film having nanoparticles in a plane at or near the surface of the film.

In some embodiments, method 400 further comprises the step of 440 incorporating the film in an OLED stack. In some embodiments, the film is applied to the top of an OLED stack, for example in the case of a top-emitting OLED stack. In some embodiments, the film is mechanically applied to the OLED stack. In some embodiments, the film is applied to the bottom substrate of the OLED stack, for example in the case of a bottom-emitting OLED stack. In these embodiments, the index of refraction of the film may greater than or equal to the index of refraction of the bottom substrate of the OLED stack. In some embodiments, the film is mechanically applied to the OLED stack. In some examples, the film is adhered to the substrate by applying the film to the OLED stack and then curing the film, or further curing the film in the case of a partially cured film. In some examples, the film is adhered to the substrate by applying an epoxy or uncured polymer layer between the film and the OLED stack then curing the epoxy or uncured polymer layer. In some embodiments, the film is applied to the OLED stack such that a surface of the film having nanoparticles is contacting the OLED stack. In some embodiments, the OLED stack is bottom-emitting and top-emitting. In these embodiments, a first film may be positioned at the top of the OLED stack and a second film may be positioned at the bottom of the OLED stack. In some embodiments, the film is applied to the OLED stack such that a textured surface of the film comprises the outermost surface of the OLED stack.

In some examples, an OLED stack is formed on top of the film, for example in the case of a bottom-emitting OLED stack. For example, the resulting film 400 may be cured while positioned in a mold, and materials for the electrode and organic layers of the OLED may be deposited directly onto the film. For example, the resulting film 400 may be cured prior to being removed from the mold, and materials for the electrode and organic layers of the OLED may be deposited directly onto the film.

In some embodiments, multiple embodiments of film 300 may be stacked prior to, during or subsequent to incorporating the film 300 in an OLED stack. Stacking one or more embodiments of film 300 may allow for the formation of a larger film 300 in which any combination of portions of film 300 or planes of film 300 comprise a plurality of nanoparticles. For example, a first film having nanoparticles embedded throughout may be stacked with a second film 300 having nanoparticles at or near one or both surfaces. In some embodiments, an imprinted film (i.e., a film having a textured surface) is stacked onto a second film that is not imprinted (i.e., a film having two non-textured surfaces). In this embodiment, a larger film may be formed having embedded nanoparticles in only a textured portion or only in a portion not having a textured surface. In other words, a film may be formed with an MLA portion and a body portion. Now referring back to FIGS. 9B and 10B, a body portion may be defined as a portion between second surface 320 and plane A. None of, one of, or both of MLA portion and body portion of a film 300 may be embedded with a plurality of nanoparticles.

In some embodiments, any properties of the polymer film and OLED stack are chosen such that the resulting OLED stack incorporating the polymer film has any plasmon outcoupling efficiency. In some examples, the polymer film outcouples at least 20% of plasmonic modes. In some embodiments, for example, in the case in which nanoparticles are embedded throughout the film, the film may outcouple 40% to 60% of waveguided modes. Plasmonic modes may typically account for 5% to 60% of photon coupling, with the exact fraction of plasmonic modes determined by the spacing between the emissive layer and the metal electrode of the OLED stack. Thus, between plasmonic modes may contribute an additional 1% to 30% to the outcoupling efficiency (i.e., the fraction of air modes). That is, in a device with 60% coupling to plasmonic modes, 20% coupling to air modes, and 20% coupling to waveguided modes, the total outcoupling expected may be 20% directly coupled to air, greater than 12% from plasmonic modes, and 4% to 8% from waveguide modes resulting in a total outcoupling efficiency of about 32% for flat films and greater than 40% for films having an MLA. The exact coupling to waveguide, air, and plasmonic modes may depend on the OLED stack, particularly the emissive layer between the two electrodes.

### OLED

In some aspects, the invention relates to an OLED incorporating a film. The OLED may be any OLED stack. The OLED may be a top-emitting OLED, a bottom-emitting OLED, or a top-emitting and bottom-emitting OLED. Incorporating a film having an MLA may be particularly advantageous for OLED stacks with thick organic layers, such as tandem structures or stacked structures, having a high fraction of photons coupling to waveguide modes.

In some embodiments, the film is an embodiment of film 300. In some embodiments, the top layer of an OLED stack comprises the film. In some embodiments, a capping layer of an OLED stack comprises the film. In some embodiments, the film is adjacent to a light-emitting metal surface of an OLED stack. In some embodiments, the bottom substrate of a bottom-emitting OLED comprises the film. In some embodiments, the top layer of a bottom-emitting and top-emitting OLED stack comprises a first film and the bottom layer of the bottom-emitting and top-emitting OLED stack comprises a second film. The first and second films may be any embodiment of film 300. In some embodiments, the film is adjacent to a cathode capping layer. For example, the cathode capping layer of an OLED may comprise MgO optionally deposited via atomic layer deposition (ALD) and the film may be positioned adjacent to the cathode capping layer surface opposite the cathode. In a transparent OLED stack, a film having an MLA may be positioned on both sides of the stack.

In some embodiments, the peak scattering wavelength of the film or the nanoparticles of the film are aligned with the wavelength of emission of the OLED stack.

In some embodiments, the index of refraction of the polymer of the film is incorporated in an OLED stack is chosen such that a desired or maximal fraction of light is coupled to plasmon modes. In some embodiments, the wavelength of emission of the OLED stack and the distance between the emission layer and the thin metal contact of the OLED stack affect the fraction of light coupled to plasmon modes in addition to the index of refraction of the polymer film.

The OLED stack incorporating the film may have any emission spectra. The OLED stack incorporating the film may have any outcoupling efficiency, external quantum efficiency (EQE), and current density-voltage-luminance (JVL). In some examples, the polymer film outcouples at least 20% of plasmonic modes. In some embodiments, for example, in the case in which nanoparticles are embedded throughout the film, the film may outcouple 40% to 60% of waveguided modes. Plasmonic modes may typically account for 5% to 60% of photon coupling, with the exact fraction of plasmonic modes determined by the spacing between the emissive layer and the metal electrode of the OLED stack. Thus, between plasmonic modes may contribute an additional 1% to 30% to the outcoupling efficiency (i.e., the fraction of air modes). That is, in a device with 60% coupling to plasmonic modes, 20% coupling to air modes, and 20% coupling to waveguided modes, the total outcoupling expected may be 20% directly coupled to air, greater than 12% from plasmonic modes, and 4% to 8% from waveguide modes resulting in a total outcoupling efficiency of about 32% for flat films and greater than 40% for films having an MLA. The exact coupling to waveguide, air, and plasmonic modes may depend on the OLED stack, particularly the emissive layer between the two electrodes.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### REFERENCES

The following publications are incorporated by reference herein in their entireties:
Fusella, M. A.; Saramak, R.; Bushati, R.; Menon, V. M.; Weaver, M. S.; Thompson, N. J.; and Brown, J. J. Plasmonic enhancement of stability and brightness in organic light-emitting devices. Nature, 2020, 585(7825), 379-382.
Sun, Yiru, and Stephen R. Forrest. “Organic light emitting devices with enhanced outcoupling via microlenses fabricated by imprint lithography.” Journal of applied physics 100, no. 7 (2006).
Zhao, H.; Arneson, C. E.; Fan, D.; Forrest, S. R. Stable Blue Phosphorescent Organic LEDs That Use Polariton-Enhanced Purcell Effects. Nature 2024, 626 (7998), 300-305.
Arneson, Claire. “Controlling Photons in Organic Light Emitting Diodes.” PhD diss., 2025.
Thomschke, M.; Reineke, S.; Lüssem, B.; Leo, K. Highly Efficient White Top-Emitting Organic Light-Emitting Diodes Comprising Laminated Microlens Films. Nano Lett. 2012, 12 (1), 424-428.
Yang, C.-J.; Liu, S.-H.; Hsieh, H.-H.; Liu, C.-C.; Cho, T.-Y.; Wu, C.-C. Microcavity Top-Emitting Organic Light-Emitting Devices Integrated with Microlens Arrays: Simultaneous Enhancement of Quantum Efficiency, Cd/A Efficiency, Color Performances, and Image Resolution. Appl. Phys. Lett. 2007, 91(25), 253508.
Liu, Y.-F.; Feng, J.; Zhang, Y.-F.; Cui, H.-F.; Yin, D.; Bi, Y.-G.; Song, J.-F.; Chen, Q.-D.; Sun, H.-B. Polymer Encapsulation of Flexible Top-Emitting Organic Light-Emitting Devices with Improved Light Extraction by Integrating a Microstructure. Org. Electron. 2014, 15 (11), 2661-2666.
Chang, H.-W.; Lee, J.; Hofmann, S.; Hyun Kim, Y.; Müller-Meskamp, L.; Lüssem, B.; Wu, C.-C.; Leo, K.; Gather, M. C. Nano-Particle Based Scattering Layers for Optical Efficiency Enhancement of Organic Light-Emitting Diodes and Organic Solar Cells. J. Appl. Phys. 2013, 113 (20), 204502.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

### Example 1: Nanoparticle-Embedded Microlens Array for Top-Emitting or Bottom-Emitting OLEDs

Previous work by Fusella, et Al. has demonstrated that metal nanoparticles can be used to couple high-k, where k is the wavevector, surface plasmon polariton modes into visible air modes (Fusella, M. A. et al. Nature, 2020, 585(7825), 379-382). The nanoparticles are dissolved in solution and spin coated onto the top of a top-emitting OLED stack. This presents a challenge for scalability and exposes the OLED to solvents which could degrade organic layers. Additionally, nanoparticle scattering layers only outcouple surface plasmon modes from the closest metal mode. Here, a design for processing nanoparticles in a polymer film that can be molded to form a microlens array and mechanically applied to the top of the OLED stack to outcouple both plasmonic and waveguided modes is presented.

The design is now described.

The goal of this design is to couple plasmonic and waveguide modes formed at the interface of organic layers and a thin metal contact into visible modes in air. This is enabled by nanoparticles that are dispersed on the metal surface through which light will be emitted, and a microscale-patterned surface to prevent reflection at the device/air interface. To avoid the highly variable and potentially damaging process of spin coating nanoparticles directly on the OLED surface, the nanoparticles are instead dispersed in a polymer. The polymer is then imprinted with a patterned microlens array (MLA).

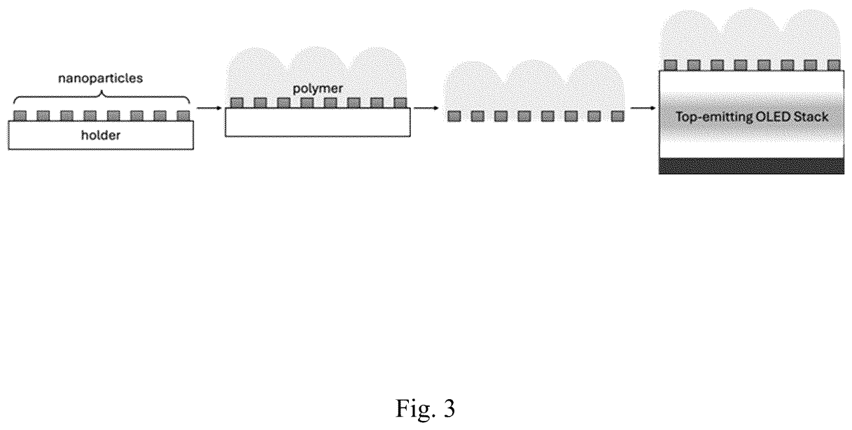

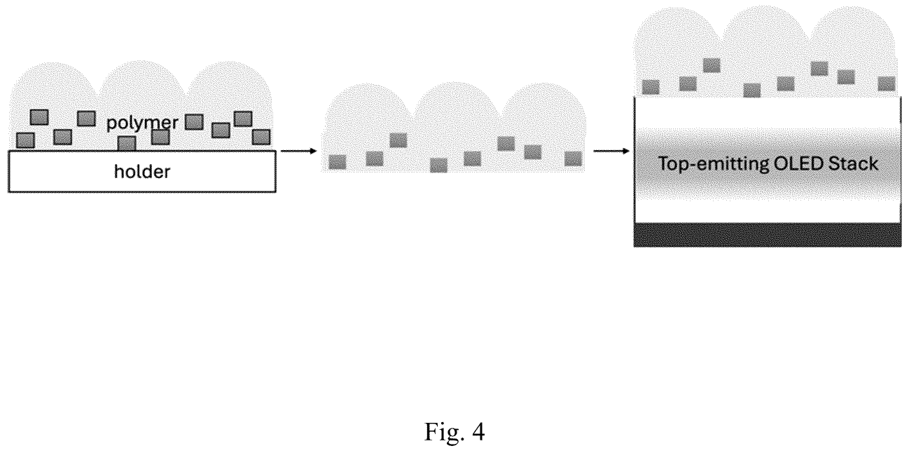

Nanoparticles can be dispersed one of two ways. In the first method, nanoparticles can be deposited on a holder substrate via solution or using nano-scale patterning of a metal film using lithography. Then, a polymer is deposited on top of the nanoparticles and imprinted with a mold etched in the desired lens pattern. The mold may be constructed from glass, polydimethylsiloxane (PDMS), or another suitable material. Ideally, the lens array is patterned in a hexagonally close-packed arrangement to eliminate planar spaces between lenses. The lens diameter should be greater than 1 μm to optimize outcoupling efficiency (Sun, Yiru, and Stephen R. Forrest. Journal of applied physics 100, no. 7 (2006)). The MLA-imprinted polymer film and nanoparticles can then be removed from holder substrate. This results in an MLA polymer film with nanoparticles embedded in its surface, illustrated in FIG. 3. In the second method, nanoparticles dispersed in solution can be mixed with polymers dissolved in a miscible solution. Then, the nanoparticle-doped polymer solution can be deposited on a holder substrate, imprinted with the desired MLA pattern, and removed using a chemical lift-off or mechanical peel-off process. This results in a polymer film doped throughout with nanoparticles, illustrated in FIG. 4. The film fabricated using one of these two methods is then applied to the light-emitting metal surface of the OLED. The film may be applied to the top surface of a top-emitting OLED. Alternatively, the NP-embedded MLA maybe used as a bottom substrate for bottom-emitting OLEDs. The size and material of nanoparticle can be tuned such that the peak scattering wavelength aligns with the wavelength of emission. Additionally, the density of nanoparticles can be varied to maximize scattering into visible air modes and minimize absorption in the nanoparticles themselves. Previous work has shown that a nanoparticle layer composed of 75 nm silver cubes randomly distributed with approximately 200 nm spacing can couple approximately 16% of surface plasmon polariton modes into air modes (Fusella, M. A. et al. Nature, 2020, 585(7825), 379-382).

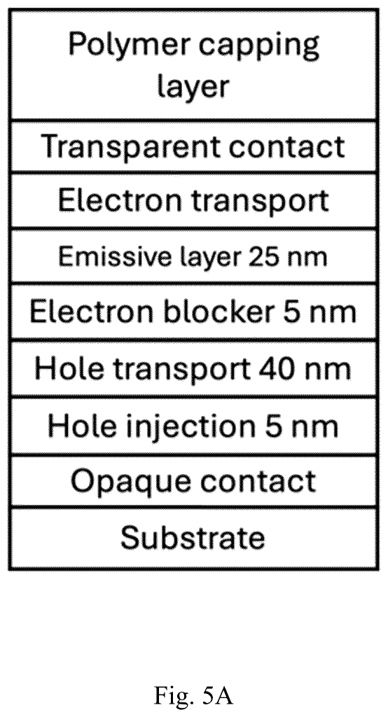

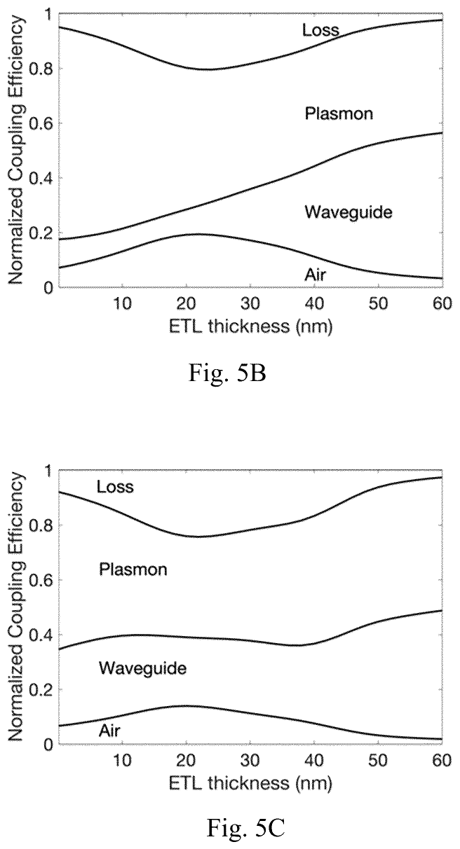

This design can be applied to any OLED stack, though the wavelength of emission and the distance between the emission layer (EML) and the thin metal contact will affect the fraction of light coupled to plasmonic modes in the metal. The transporting layer material that lies between the EML and the thin metal contact can be either hole or electron transporting, and can be chosen to form either surface plasmon polariton or plasmon-exciton-polariton modes at the metal surface. This was demonstrated in previous work by Zhao, et Al. An example structure is shown in FIG. 5A (Zhao, H. et al. Nature 2024, 626 (7998), 300-305).

The polymer material should be chosen to have a high index of refraction, approximately n=2.0, such that the fraction of light coupled to plasmon modes is maximized. For capping layers with n=2.0, the fraction of light coupled to plasmon modes can be up to 1.5× greater than for capping layers with n=1.5, shown in FIG. 5B and FIG. 5C.

The results of the Example are now described.

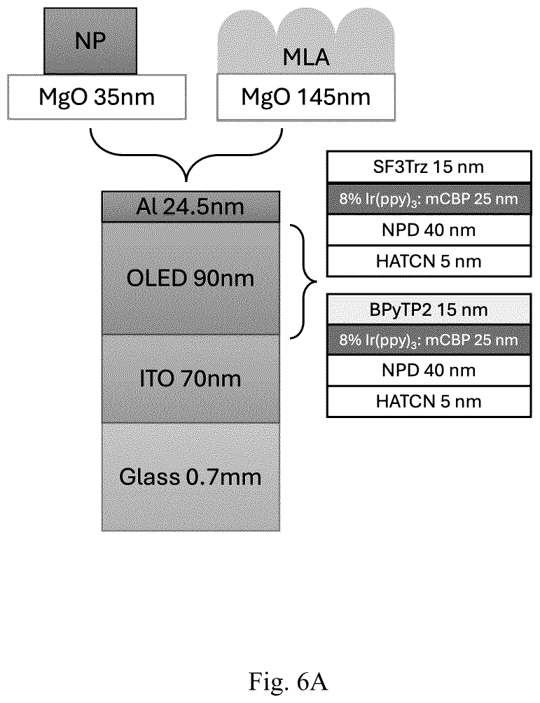

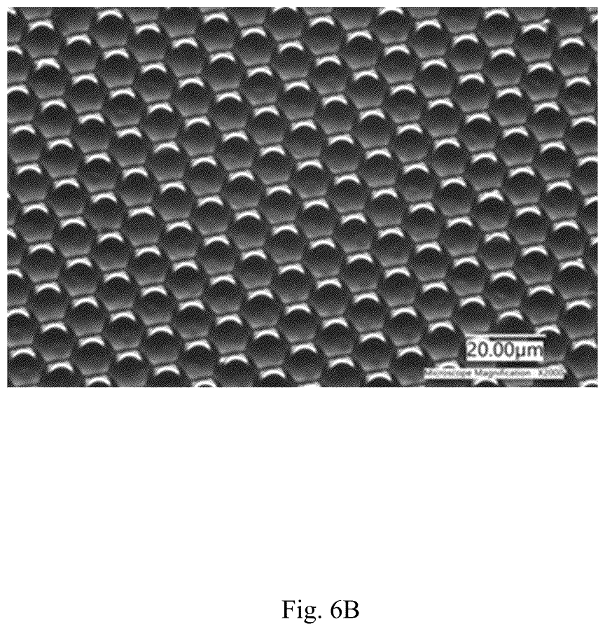

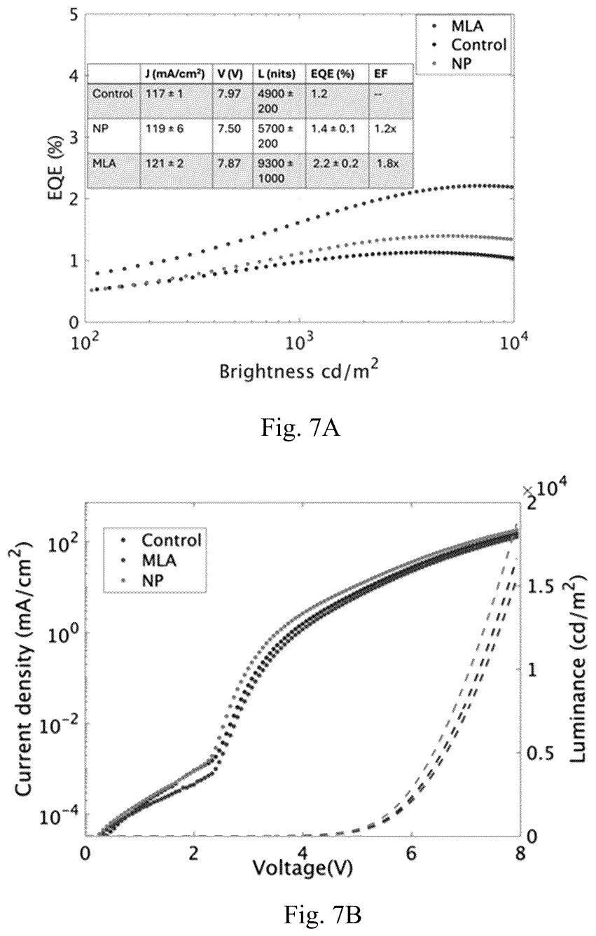

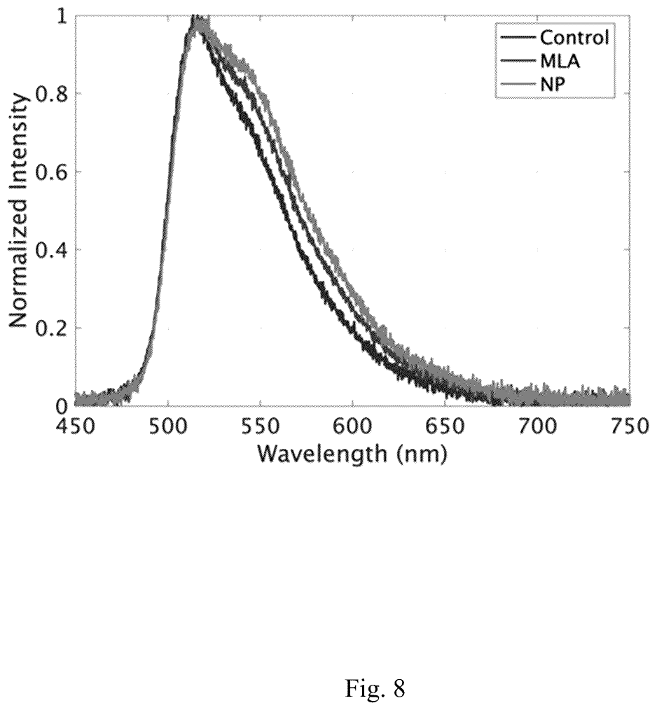

The effectiveness of a high-index MLA for plasmonic mode outcoupling compared to an Ag nanoparticle scattering layer was tested (Arneson, Claire. “Controlling Photons in Organic Light Emitting Diodes.” PhD diss., 2025). The high index polymer, purchased from Pixelligent, contains a polymer base doped with 20 nm diameter TiO2 nanospheres. The current density-voltage-luminance (JVL) and external quantum efficiency (EQE) for the control, MLA, and nanoparticle only devices are shown in FIG. 6. A summary of the device parameters is included in the inset table. The largest enhancement for devices was observed with the MLA, achieving a 1.8× enhancement in EQE. The device emission spectra are shown in FIG. 7. The spectra for both nanoparticle and MLA devices are broadened relative to the control, with the nanoparticle device showing slightly broader emission than the MLA. It was predicted that with the proposed nanoparticle-embedded MLA, a higher outcoupling efficiency could be achieved.

The device structure used in this Example was designed with a thin ETL to maximize coupling to the top cathode plasmon mode. SF3Trz and BPyTP2 were chosen for the devices, respectively, because of their well-characterized polaritonic behavior (Zhao, H. et al. Nature 2024, 626 (7998), 300-305). MgO deposited via ALD was used for the cathode capping layer because it has an index of refraction matching that of the EML and the ALD provides conformal coating to protect the organic layers during application of external enhancement layers. A transparent ITO anode and thing Ag cathode were used, enabling both TE and BE, to isolate the outcoupling enhancement from the top contact plasmon modes. As a result the observed EQE for all devices was relatively low.

The use of an MLA attached directly to the capping layer of the device was investigated. Previous work using a MLA on TE devices has achieved EQE enhancements ranging from 1.1-1.5× for MLAs with n=1.5-1.7 (Thomschke, M. et al. Nano Lett. 2012, 12 (1), 424-428., Yang, C.-J. et al. Appl. Phys. Lett. 2007, 91 (25), 253508, Liu, Y.-F. et al. Org. Electron. 2014, 15 (11), 2661-2666.). Here, a high index polymer with n˜1.85 was used. It was observed that the 1.9× outcoupling enhancement of the MLA outperforms the nanoparticle enhancement layer and provides greater enhancement than in previous works. The width of the spectrum for MLA devices falls between the control and nanoparticle devices.

The thin ETL structure completely suppresses waveguided modes between the ITO anode and Ag cathode are by coupling to the plasmon mode. The MgO capping layer does trap some waveguided modes, 0.58<u<1, which are then propagated into the higher index MLA for devices with the additional external enhancement layer.

When the MLA was added, the fraction of light trapped in the MgO/MLA layer waveguide mode decreased from 15% to 10%. In the control device, however, the fraction of waveguided light cannot be extracted; the MLA can scatter these modes into visible modes, thus leading to the observed enhancement. The majority of the modes outcoupled by the MLA are waveguide modes with u<1, but it is possible that some plasmon modes are outcoupled as well. The commercial high-index polymer used was doped with 20 nm diameter TiO2 nanospheres. The optimal diameter for nanoparticle scatterers is on the order of ˜100 nm, so scattering from within the MLA is likely low. The performance of the MLA could potentially be enhanced by replacing the scattering centers with larger diameter nanoparticles, which has been demonstrated in BE devices previously (Chang, H.-W. et al. J. Appl. Phys. 2013, 113 (20), 204502).

### Example 2: Improving Plasmonic Mode Outcoupling Through the Use of Plasmon-Exciton-Polaritons and Nanoparticle Scatterers

Recent work on blue phosphorescent organic light emitting diodes (OLEDs) has demonstrated that the operational lifetime can be extended through the coupling of excitons in organic transport layers to plasmonic modes in the metal cathode, forming hybrid plasmon-exciton-polaritons (PEPs) (1. Zhao, H. et al. Nature, 626 (7998), 300-305., Zhao, H. et al. Nature Photonics, 1-8.). The thin spacing between the emissive layer and Ag cathode necessary to form PEP modes results in 40-60% of photons trapped in plasmonic modes. It has been demonstrated that Ag nanoparticle scatterers can be used to outcouple surface plasmon modes in top emitting OLEDs (Fusella, M. A. et al. (2020). Plasmonic enhancement of stability and brightness in organic light-emitting devices. Nature, 585(7825), 379-382). In this Example, it was demonstrated that the outcoupling enhancement of a nanoparticle scattering layer can be improved by 1.2× using a PEP-forming electron transport layer (ETL) compared to a control, (surface plasmon polariton-forming ETL (SPP-forming ETL)). Using k-space-resolved photoluminescence, it was demonstrated that the addition of nanoparticles results in scattering of trapped plasmon modes with high-k into visible low-k air modes. The use of nanoparticles with a PEP ETL resulted in a 1.5× increase in outcoupled air modes, compared to 1.05× with a surface plasmon polariton (SPP) ETL. It was demonstrated that in a green phosphorescent, top-emitting OLED the external quantum efficiency can be enhanced by 1.4× in a PEP device with a nanoparticle scattering layer, compared to 1.2× in SPP devices. The observed enhancement in outcoupling from SPP to PEP devices suggests that existing plasmon outcoupling structures can be enhanced through strategic choice of a PEP-forming ETL/metal materials. The work of this example provides for improving the efficiency of phosphorescent OLEDs that are compatible with operationally stable device structures.

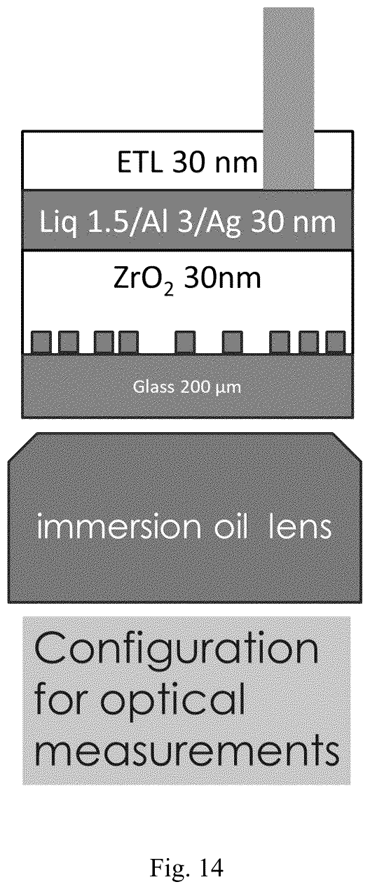

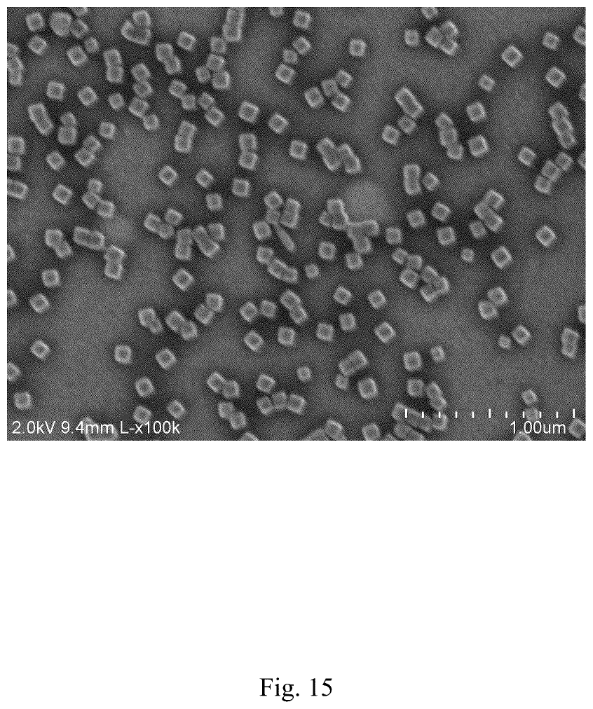

It has been demonstrated that plasmonic modes can be outcoupled using Ag nanocubes to scatter SPP modes from the metal cathode surface into visible air modes (Fusella, M. A., et al. “Plasmonic enhancement of stability and brightness in organic light-emitting devices.” Nature, 2020). In this Example, the efficiency of nanoparticle (NP) outcoupling was characterized in PEP vs SPP devices by measuring the photoluminescence (PL) as a function of the normalized in-plane wavevector, k=k_{∥}/k₀, using Fourier plane microscopy (Kim, J., et al. “Using Fourier-plane imaging microscopy for determining transition-dipole-moment orientations in organic light-emitting devices.” Phys. Rev. Appl., 2020). A polarizer was used to measure only the TM mode. A schematic of the configuration for optical measurements used in the Example is depicted in FIG. 14.

FIG. 15 depicts a scanning electron microscope (SEM) image of 75 nm Ag nanocubes on ALD-grown ZrO₂. Nanocubes were spin coated from 10 mg/mL suspension in ethanol.

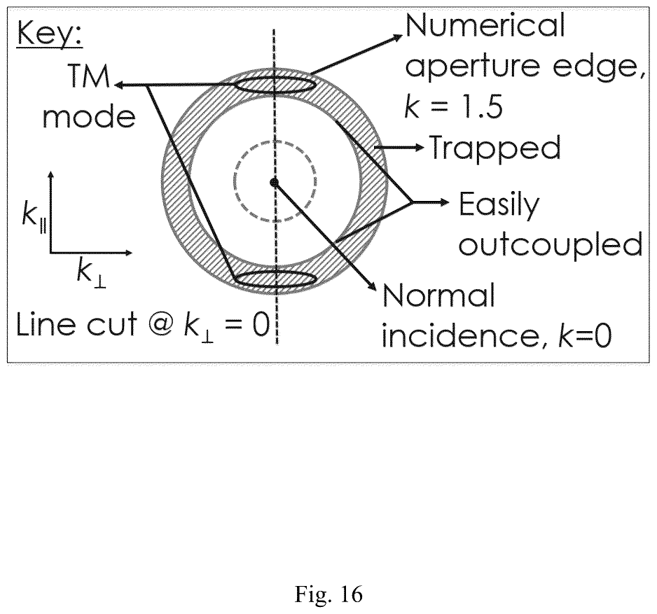

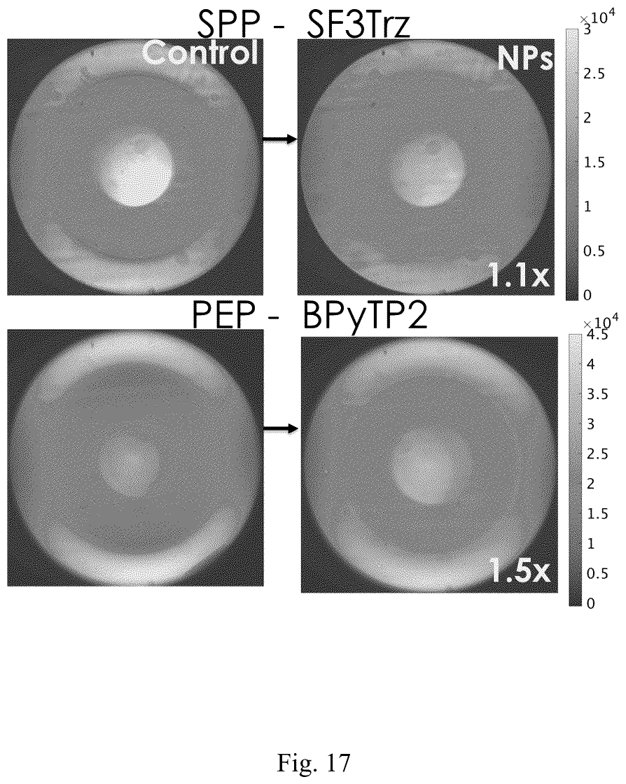

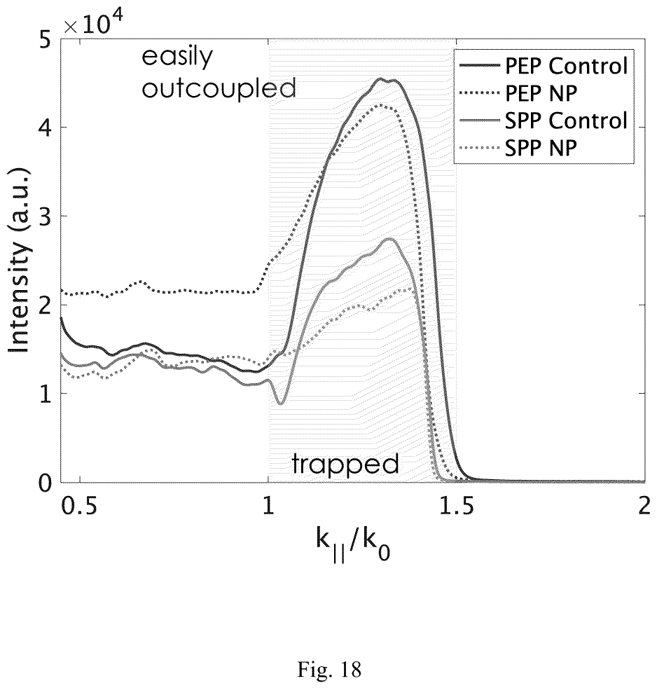

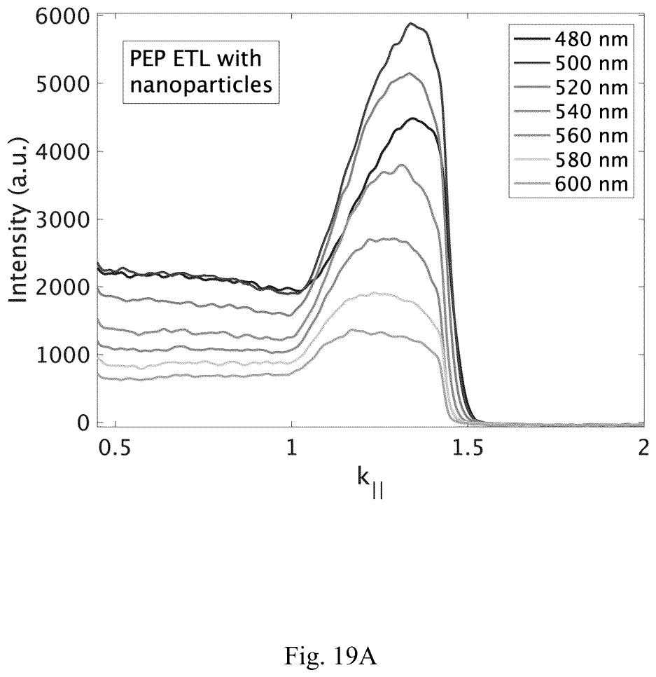

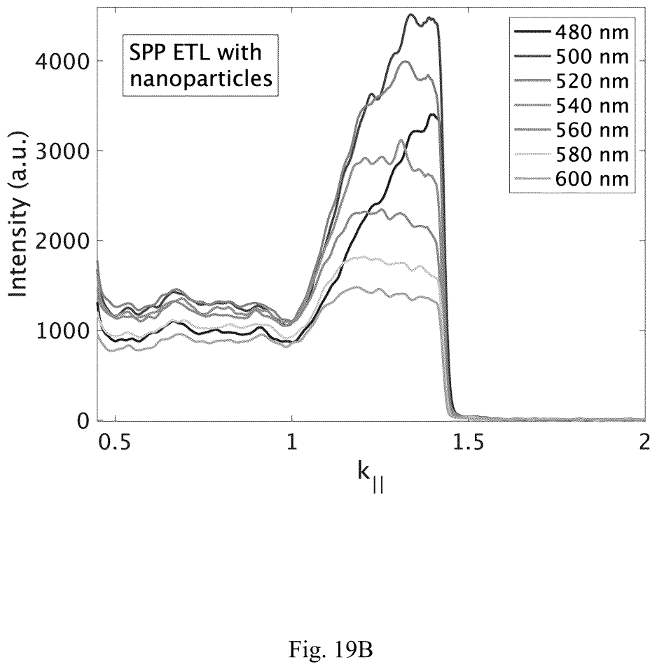

FIG. 16 depicts a schematic for the visualization of modes. The addition of NPs decreased the PL intensity in trapped (k>1) modes while increasing the easily outcoupled (k<1) modes. The PEP samples showed a 1.5× enhancement in easily outcoupled modes, compared to 1.1× in the SPP samples. Integrated PL intensity is depicted in FIG. 17. Linecut of integrated PL intensity at k⊥=0 is depicted in FIG. 18. The PL intensity in the PEP sample is about 1.5× brighter compared to the SPP samples. With a PEP ETL, as the emission wavelength approaches the ETL exciton energy it becomes more PEP-like and has increased scattering to k<1 (air) modes (FIG. 19A). As the emission red-shifts, it becomes more SPP-like (FIG. 19B).

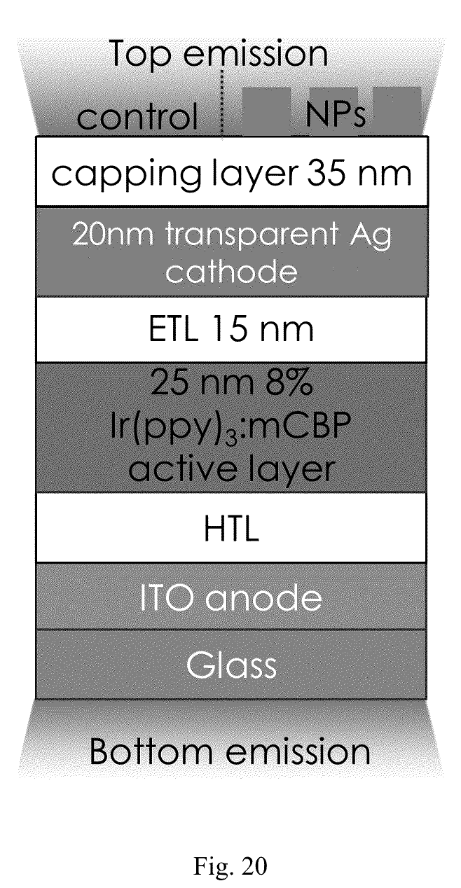

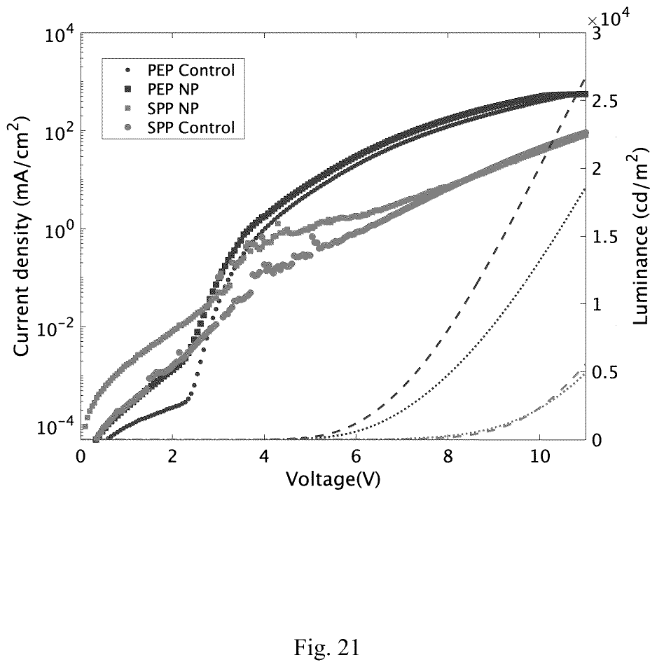

A schematic of a transparent green OLED of the Example is depicted in FIG. 20. J-V-L characteristics for control and NP-enhance devices are depicted in FIG. 21. J-V-L characteristics for control are depicted as dots a circles, and J-V-L characteristics for NP-enhance devices are depicted as dashes and squares. J-V-L characteristics are shown for control and NP-enhanced SPP and PEP devices (Table 1, below).

TABLE 1

| | Top-emission only | | | | Top & bottom | |
|---|---|---|---|---|---|---|
| | V | J | L | Enhancement | L | EE |
| | (V) | (mA/cm²) | (cd/m²) | Factor | (cd/m²) | (%) |
| SPP | 11.2 | 93 ± 8 | 5540 ± 10 | — | — | — |
| PEP | 7.93 | 153 ± 6 | 5450 ± 70 | — | — | — |
| SPP + NP | 11.25 | 100 ± 10 | 6600 ± 400 | 1.19 ± 0.07 | 25000 ± | 7 ± 0.1 |
| | | | | | 400 | |
| PEP + NP | 7.73 | 158 ± 5 | 7680 ± 200 | 1.41 ± 0.05 | 24000 ± | 4.3 ± 0.2 |
| | | | | | 200 | |

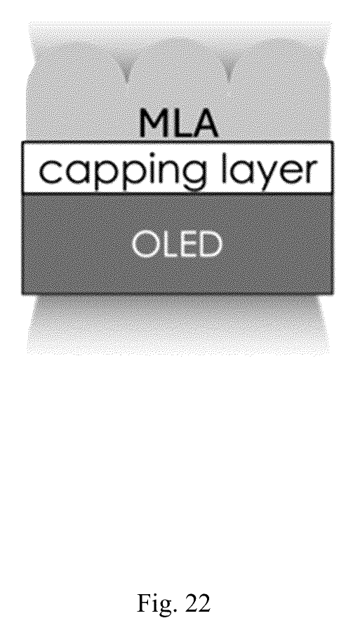

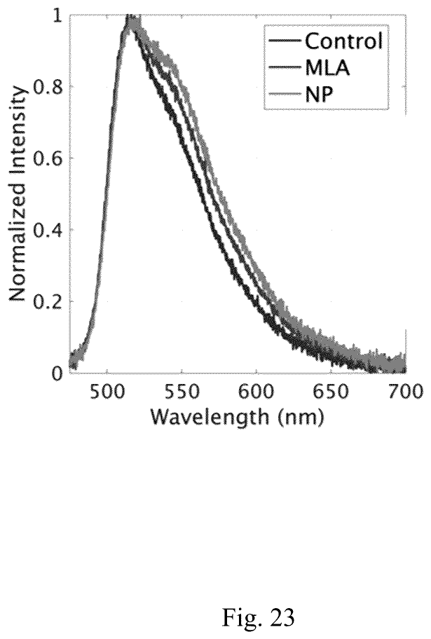

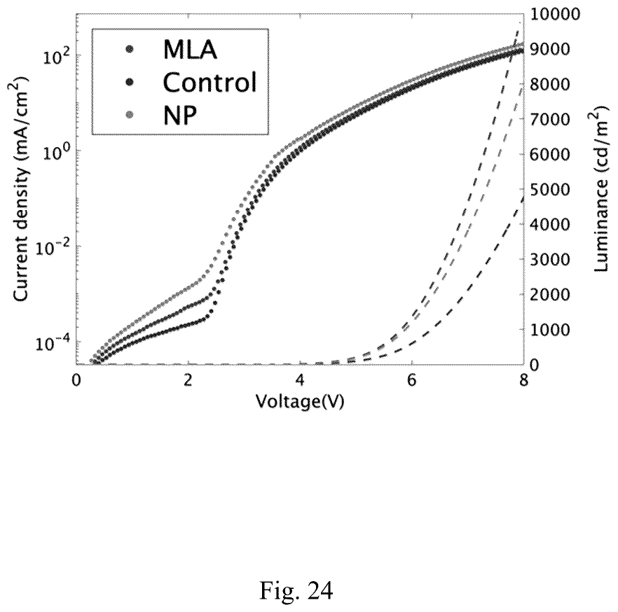

A schematic of a transparent PEP device with a microlens array (MLA) of the example is depicted in FIG. 22. FIG. 23 shows a graph of normalized intensity against wavelength for a control transparent PEP device, a transparent PEP device with an MLA, and a transparent PEP device with nanoparticles (NPs). FIG. 24 shows a graph of current density (mA/cm²) and Luminance (cd/m²) against voltage (V) a control transparent PEP device, a transparent PEP device with an MLA, and a transparent PEP device with nanoparticles (NPs). JVL characteristics are shown for a control transparent PEP device, a transparent PEP device with nanoparticles, and a transparent PEP device with a microlens array (MLA) (Table 2, below).

TABLE 2

| | J (mA/cm²) | V (V) | L (cd/m²) | EQE (%) | EF |
|---|---|---|---|---|---|
| Control | 117 ± 1 | 7.97 | 4900 ± 200 | 1.20 ± 0.05 | — |
| NP | 119 ± 6 | 7.50 | 5700 ± 200 | 1.4 ± 0.1 | 1.2 ± 0.1 |
| MLA | 121 ± 2 | 7.87 | 9300 ± 1000 | 2.2 ± 0.2 | 1.8 ± 0.2 |

Conclusions of the Example are now described. PEP-enhanced electrodes have demonstrated improved lifetime, tunability for different emission wavelengths, and compatibility with multiple emitter types. The extraction efficiency of plasmonic modes can be enhance by in the range of 1.2 to 1.5 times by designing PEP-forming electrodes. This enhances device efficiency which further improves lifetime. PEP-enhanced extraction is compatible with any plasmonic outcoupling structure. In contrast, spin-coated nanoparticles are limited in their scalability and reproducibility.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. A film comprising:
a first surface;
a second surface opposite the first surface;
a volume between the first surface and the second surface, the volume comprising a polymer; and
one or more nanoparticles comprising a metal.

2. The film of claim 1, wherein the first surface comprises a micro-scale pattern

3. The film of claim 2, wherein the micro-scale pattern comprises a microlens array (MLA).

4. (canceled)

5. The film of claim 1, wherein at least one of the one or more nanoparticles is positioned at the second surface.

6. The film of claim 1, wherein at least one of the one or more nanoparticles is embedded in the volume of the film.

7. The film of claim 1, wherein the polymer has an index of refraction larger than 1.5.

8. The film of claim 1, wherein the metal is selected from the group consisting of: Ag, Al, Au, Ir, Pt, Ni, Cu, W, Ta, Fe, Cr, Mg, Ga, Rh, Ti, Ru, Pd, In, Bi, Ca, alloys thereof, mixtures thereof, and stacks thereof.

9. The film of claim 3, wherein the microlens array comprises at least one lens having a diameter of at least 1 μm.

10. The film of claim 3, wherein the microlens array comprises a polygonally close-packed lens arrangement.

11. The film of claim 1, wherein at least one of the one or more nanoparticles has at least one dimension larger than 20 nm.

12-28. (canceled)

29. A consumer product comprising a display device comprising the film of claim 1, wherein the consumer product is selected from the group consisting of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a light therapy device, an optical communication device, and a sign.

30. (canceled)

31. A device comprising:
a substrate
a first electrode;
a first organic emissive layer (EML) disposed over the first electrode, the first EML comprising a first emissive material;
a second electrode disposed over the first EML; and
a film comprising:
a first surface;
a second surface opposite the first surface
a volume between the first surface and the second surface, the volume comprising a polymer; and
one or more nanoparticles comprising a metal.

32. (canceled)

33. The device of claim 31, wherein the second electrode comprises an enhancement layer.

34. The device of claim 33, wherein the enhancement layer comprises a plasmonic material exhibiting surface plasmon resonance that non-radiatively couples to the organic emissive material and transfers excited state energy from the organic emissive material to non-radiative mode of surface plasmon polaritons.

35. The device of claim 34, wherein the enhancement layer is provided no more than a threshold distance away from the organic emissive material, wherein the organic emissive material has a total non-radiative decay rate constant and a total radiative decay rate constant due to the presence of the enhancement layer, and the threshold distance is where the total non-radiative decay rate constant is equal to the total radiative decay rate constant.

36. The device of claim 34, wherein the enhancement layer is provided no more than a threshold distance away from the organic emissive material, wherein the organic emissive material has a total non-radiative decay rate constant
$${k}_{n o n - r a d}^{0} ,$$
a total radiative decay rate constant
$${k}_{r a d}^{0} ,$$
a total non-radiative decay rate constant due to the enhancement layer
$${k}_{non - r ad}^{plasmon} ,$$
and a total radiative decay rate constant due to the enhancement layer
$${k}_{r a d}^{p l a s m o n} ;$$
wherein the threshold distance is a distance at which
$$\frac{{k}_{r a d}^{p l a s m o n}}{{k}_{non - r ad}^{plasmon}} = \frac{{k}_{r ad}^{0}}{{k}_{non - r ad}^{0}} .$$

37. The device of claim 31, wherein the second electrode is positioned on the emission side of the device.

38. The device of claim 31, wherein the film is configured to couple polariton modes to air modes at a surface of the second electrode with a 20% to 60% coupling efficiency.

39. The device of claim 31, wherein a peak scattering wavelength of the one or more nanoparticles of the film is aligned with a wavelength of emission of the device.

40. A consumer product comprising the device of claim 31, wherein the consumer product is selected from the group consisting of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a light therapy device, an optical communication device, and a sign.
